(19) United States
(12) Patent Application Publication
(10) Pub. No.: US 2015/0232988 A1
(43) Pub. Date: Aug. 20, 2015

(54) VAPOR PHASE GROWTH APPARATUS

(71) Applicants: TAIYO NIPPONSANSO CORPORATION, Tokyo (JP); TN EMC LTD., Tokyo (JP)

(72) Inventors: Akira Yamaguchi, Tokyo (JP); Akinori Ubukata, Tokyo (JP); Yuya Yamaoka, Tokyo (JP); Kosuke Uchiyama, Kawasaki (JP)

(73) Assignee: TAIYO NIPPON SANSO CORPORATION et al.

(21) Appl. No.: 14/427,237

(22) PCT Filed: Sep. 26, 2013
(86) PCT No.: PCT/JP2013/076091

§ 371 Date: Mar. 10, 2015

(30) Foreign Application Priority Data
Oct. 4, 2012 (JP) 2012-221856
Oct. 4, 2012 (JP) 2012-221858
Oct. 4, 2012 (JP) 2012-221860

(51) Int. Cl. C23C 16/458; C23C 16/52

(52) U.S. Cl. CPC C23C 16/4583; C23C 16/4584; C23C 16/52; C23C 16/4585

(57) ABSTRACT

Provided is a high-productivity, compact vapor phase growth apparatus 1. This vapor phase growth apparatus 1 is configured to supply a raw material gas onto a substrate 5 placed in a chamber 2 that can be vertically divided into a chamber main body 3 and a chamber cover 4 to cause a thin film to grow on the substrate 5. This vapor phase growth apparatus 1 includes a susceptor 7 formed from a circular plate that is detachably arranged on the chamber main body 3 side and is configured to hold the substrate 5, a susceptor cover 9 to be placed on the susceptor 7 so as to cover a region other than a substrate holding portion of the susceptor 7, a ceiling plate 11 that is provided separated from the susceptor 7 by a predetermined interval and faces the susceptor 7 to form a flow path of the raw material gas, and a temporary placement apparatus 21 configured to temporarily place at least one of the susceptor 7, the susceptor cover 9, and the ceiling plate 11 in a space above the chamber main body 3 formed when the chamber 2 has been divided.

### TECHNICAL FIELD

The present invention relates to a vapor phase growth apparatus configured to supply a raw material gas onto a substrate arranged in a reaction furnace to cause a thin film to grow on the substrate.

### BACKGROUND ART

A vapor phase growth method is a thin film formation method in which a raw material is deposited on a substrate surface by a chemical reaction by supplying a thin film raw material in a gaseous state onto the substrate. For example, a GaN semiconductor thin film, which is a material for blue light emitting diodes, green light emitting diodes, and violet laser diodes, is produced based on a MOCVD (metal organic chemical vapor deposition) method that uses an organic metal as a raw material.

Patent Literature 1 discloses an example of a vapor phase growth apparatus configured to grow a semiconductor thin film utilizing a vapor phase growth method. The vapor phase growth apparatus disclosed in the Patent Literature 1 is a rotation/revolution type vapor phase growth apparatus in which a susceptor on which a plurality of substrates are placed is arranged in a chamber that serves as a vapor phase growth reaction furnace. This rotation/revolution type vapor phase growth apparatus is configured to grow a semiconductor thin film by supplying a raw material gas including the materials for the semiconductor thin film in all directions from a nozzle provided in the center of the chamber. For such a vapor phase growth apparatus, there is a trend toward an increase in the size of the chamber in order to improve the productivity of the semiconductor thin film. In conjunction with this, the size of the members in the chamber, such as the susceptor cover and the susceptor, is also increasing.

In such a vapor phase growth apparatus, when deposition finishes, reactive products are adhered to members such as the ceiling plate. If deposition is allowed to continue with these products left as is, a part of the constituent metals included in the adhered products are liquefied during deposition and disperse in the chamber, which can adversely affect deposition. Consequently, there is a need to replace the used ceiling plate and the like with new parts. However, to improve replacement efficiency, generally, like the vapor phase growth apparatus disclosed in Patent Literature 1, a space is secured for temporarily holding members such as the ceiling plate in a glove box (refer to paragraph [0032] and FIG. 6 of Patent Literature 1).

### CITATION LIST

### Patent Literature

### [Patent Literature 1]

Japanese Patent Application Laid-Open No. 2010-255083

### SUMMARY OF INVENTION

### Technical Problem

However, as described above, there is the problem that if a space is secured for temporarily holding members such as the ceiling plate, the size of the apparatus itself increases. In addition, as described above, the size of members such as the ceiling plate is increasing, and this problem is becoming more and more apparent.

Further, although replacement of the ceiling plate and the like is carried out by a robot arm arranged in a glove box, since the replacement space is provided at a separate location to the chamber, there are the problems that the cycle time required for replacement lengthens, and productivity deteriorates.

The present invention is created to solve such problems, and thus it is an object of the present invention to provide a high-productivity, compact vapor phase growth apparatus.

### Solution to Problem

(1) A vapor phase growth apparatus configured to supply a raw material gas onto a substrate arranged in a chamber that can be vertically divided into a chamber main body and a chamber cover to cause a thin film to grow on the substrate, the vapor phase growth apparatus including:

a susceptor formed from a circular plate that is detachably arranged on the chamber main body side and is configured to hold the substrate;

a susceptor cover to be placed on the susceptor so as to cover a region other than a substrate holding portion of the susceptor;

a ceiling plate that is provided separated from the susceptor by a predetermined interval and faces the susceptor to form a flow path of the raw material gas; and

a temporary placement apparatus configured to temporarily place at least one of the susceptor, the susceptor cover, and the ceiling plate in a space above the chamber main body formed when the chamber has been divided.

(2) Further, the vapor phase growth apparatus according to (1),

wherein the temporary placement apparatus includes one or a plurality of temporary placement arms capable of entering and exiting the space above the chamber main body, and

wherein the one or a plurality of temporary placement arms include at a tip thereof a temporary placement portion for temporary placement of at least one of the susceptor, the susceptor cover, and the ceiling plate.

(3) Still further, the vapor phase growth apparatus according to (1) or (2), wherein the temporary placement apparatus includes:

a ceiling plate temporary placement portion for temporary placement of the ceiling plate; and

a susceptor temporary placement portion for temporary placement of the susceptor on which the susceptor cover is placed or the susceptor cover.

(4) Still further, the vapor phase growth apparatus according to (3),

wherein the temporary placement portion is configured from two vertical steps of an upper step support portion and a lower step support portion,

wherein the upper step support portion is the ceiling plate temporary placement portion, and

wherein the lower step support portion is the susceptor temporary placement portion.

(5) Still further, the vapor phase growth apparatus according to any one of (1) to (4), wherein the temporary placement apparatus includes a centering mechanism configured to align a center of the temporarily placed susceptor, susceptor cover, or ceiling plate with a center of the chamber main body.
(6) Still further, the vapor phase growth apparatus according to (5), wherein the centering mechanism includes a centering piece configured to abut an outer periphery portion of the temporarily placed susceptor, susceptor cover, or ceiling plate at at least three locations, and slightly move the susceptor, susceptor cover, or ceiling plate in a center direction.
(7) Still further, the vapor phase growth apparatus according to (6),

wherein the centering piece can be made to protrude based on compressed air.

(8) Still further, the vapor phase growth apparatus according to any one of (1) to (7), further including:

a transfer arm configured to transfer at least one of the susceptor, the susceptor cover, and the ceiling plate into and out of the chamber;

a nozzle portion configured to ascendably/descendably support the ceiling plate and to supply the raw material gas;

an upthrust ascent/descent mechanism configured to thrust up and ascendably/descendably support from below the susceptor on which placed the susceptor cover is placed or the susceptor cover; and

a control unit configured to control operation of the transfer arm, the nozzle portion, the upthrust ascent/descent mechanism, and the temporary placement apparatus.

(9) Still further, the vapor phase growth apparatus according to (8),

wherein a plurality of through holes are provided on an outer periphery portion of the susceptor, and

wherein the upthrust ascent/descent mechanism includes:
a plurality of upthrust rods ascendably/descendably erected on an outer periphery portion of the chamber main body;
ascent/descent means configured to, normally, position an upper end surface of each upthrust rod lower than the susceptor in a state in which the susceptor is provided on the chamber side, and during operation, raise the upper end surface of each upthrust rod above the susceptor cover placed on the susceptor in a state in which the susceptor is provided on the chamber side; and
a function of selecting whether to thrust up the susceptor or to thrust up the susceptor cover by controlling a relative position between a position of each of the through holes and the upper end faces of the upthrust rods by rotating the susceptor.
   (10) Still further, the vapor phase growth apparatus according to any of (1) to (9),

wherein the control unit includes a program configured to realize:

a step of transferring with the transfer arm and handing over and holding in the temporary placement apparatus at least one of the susceptor, the susceptor cover, and the ceiling plate;

a step of raising the ceiling plate with the nozzle portion;

a step of raising the susceptor and/or the susceptor cover with the upthrust ascent/descent mechanism;

a step of handing over and transferring a member held by the nozzle portion and/or the upthrust ascent/descent mechanism to the transfer arm;

a step of delivering the ceiling plate to the nozzle portion from the temporary placement apparatus in a state in which the ceiling plate is held; and

a step of delivering the susceptor and/or the susceptor cover to the upthrust ascent/descent mechanism from the temporary placement apparatus in a state in which the susceptor and the susceptor cover are held.

(11) Still further, the vapor phase growth apparatus according to (8) to (10),

wherein the transfer arm comprises:
an upper step portion configured to hold the ceiling plate; and
a lower step support portion configured to hold the susceptor and the susceptor cover, or the susceptor cover, and

wherein the transfer arm is capable of holding so that a member held by the upper step support portion and a member held by the lower step support portion do not contact each other.

### Advantageous Effects of Invention

According to the present invention, a high-productivity, compact vapor phase growth apparatus can be provided by including a temporary placement apparatus capable of temporarily placing at least one of a susceptor, a susceptor cover, and a ceiling plate in a space above a chamber main body formed when the chamber has been divided.

### BRIEF DESCRIPTION OF DRAWINGS

FIG. 1 is a sectional elevational view (Part 1) of a vapor phase growth apparatus according to an embodiment of the present invention.

FIG. 2 is a sectional elevational view (Part 2) of a vapor phase growth apparatus according to an embodiment of the present invention.

FIG. 3 is an explanatory diagram (Part 1) illustrating the members configuring the vapor phase growth apparatus illustrated in FIG. 1.

FIG. 4 is an explanatory diagram (Part 2) illustrating the members configuring the vapor phase growth apparatus illustrated in FIG. 1.

FIG. 5 is an explanatory diagram (Part 1) illustrating operation of the vapor phase growth apparatus illustrated in FIG. 1.

FIG. 6 is an explanatory diagram (Part 2) illustrating operation of the vapor phase growth apparatus illustrated in FIG. 1.

FIG. 7 is an explanatory diagram (Part 3) illustrating the members configuring the vapor phase growth apparatus illustrated in FIG. 1.

FIG. 8 is an explanatory diagram (Part 4) illustrating the members configuring the vapor phase growth apparatus illustrated in FIG. 1.

FIG. 9 is an explanatory diagram (Part 1) illustrating a step in an example of a transfer method using the vapor phase growth apparatus illustrated in FIG. 1.

FIG. 10 is an explanatory diagram (Part 2) illustrating a step in an example of a transfer method using the vapor phase growth apparatus illustrated in FIG. 1.

FIG. 11 is an explanatory diagram (Part 3) illustrating a step in an example of a transfer method using the vapor phase growth apparatus illustrated in FIG. 1.

FIG. 12 is an explanatory diagram (Part 4) illustrating a step in an example of a transfer method using the vapor phase growth apparatus illustrated in FIG. 1.

FIG. 13 is an explanatory diagram (Part 5) illustrating a step in an example of a transfer method using the vapor phase growth apparatus illustrated in FIG. 1.

FIG. 14 is an explanatory diagram (Part 6) illustrating a step in an example of a transfer method using the vapor phase growth apparatus illustrated in FIG. 1.

FIG. 15 is an explanatory diagram (Part 7) illustrating a step in an example of a transfer method using the vapor phase growth apparatus illustrated in FIG. 1.

FIG. 16 is an explanatory diagram (Part 8) illustrating a step in an example of a transfer method using the vapor phase growth apparatus illustrated in FIG. 1.

FIG. 17 is an explanatory diagram (Part 9) illustrating a step in an example of a transfer method using the vapor phase growth apparatus illustrated in FIG. 1.

FIG. 18 is an explanatory diagram (Part 10) illustrating a step in an example of a transfer method using the vapor phase growth apparatus illustrated in FIG. 1.

FIG. 19 is an explanatory diagram (Part 11) illustrating a step in an example of a transfer method using the vapor phase growth apparatus illustrated in FIG. 1.

FIG. 20 is an explanatory diagram (Part 1) illustrating a step in another example to that of FIGS. 9 to 19 of a transfer method using the vapor phase growth apparatus illustrated in FIG. 1.

FIG. 21 is an explanatory diagram (Part 2) illustrating a step in another example to that of FIGS. 9 to 19 of a transfer method using the vapor phase growth apparatus illustrated in FIG. 1.

FIG. 22 is an explanatory diagram (Part 3) illustrating a step in another example to that of FIGS. 9 to 19 of a transfer method using the vapor phase growth apparatus illustrated in FIG. 1.

FIG. 23 is an explanatory diagram (Part 4) illustrating a step in another example to that of FIGS. 9 to 19 of a transfer method using the vapor phase growth apparatus illustrated in FIG. 1.

FIG. 24 is an explanatory diagram (Part 5) illustrating a step in another example to that of FIGS. 9 to 19 of a transfer method using the vapor phase growth apparatus illustrated in FIG. 1.

FIG. 25 is an explanatory diagram (Part 6) illustrating a step in another example to that of FIGS. 9 to 19 of a transfer method using the vapor phase growth apparatus illustrated in FIG. 1.

FIG. 26 is an explanatory diagram (Part 7) illustrating a step in another example to that of FIGS. 9 to 19 of a transfer method using the vapor phase growth apparatus illustrated in FIG. 1.

FIG. 27 is an explanatory diagram (Part 8) illustrating a step in another example to that of FIGS. 9 to 19 of a transfer method using the vapor phase growth apparatus illustrated in FIG. 1.

FIG. 28 is an explanatory diagram (Part 9) illustrating a step in another example to that of FIGS. 9 to 19 of a transfer method using the vapor phase growth apparatus illustrated in FIG. 1.

FIG. 29 is an explanatory diagram (Part 10) illustrating a step in another example to that of FIGS. 9 to 19 of a transfer method using the vapor phase growth apparatus illustrated in FIG. 1.

FIG. 30 is an explanatory diagram (Part 11) illustrating a step in another example to that of FIGS. 9 to 19 of a transfer method using the vapor phase growth apparatus illustrated in FIG. 1.

FIG. 31 is an explanatory diagram of another mode of a susceptor of the vapor phase growth apparatus according to an embodiment.

### DESCRIPTION OF EMBODIMENTS

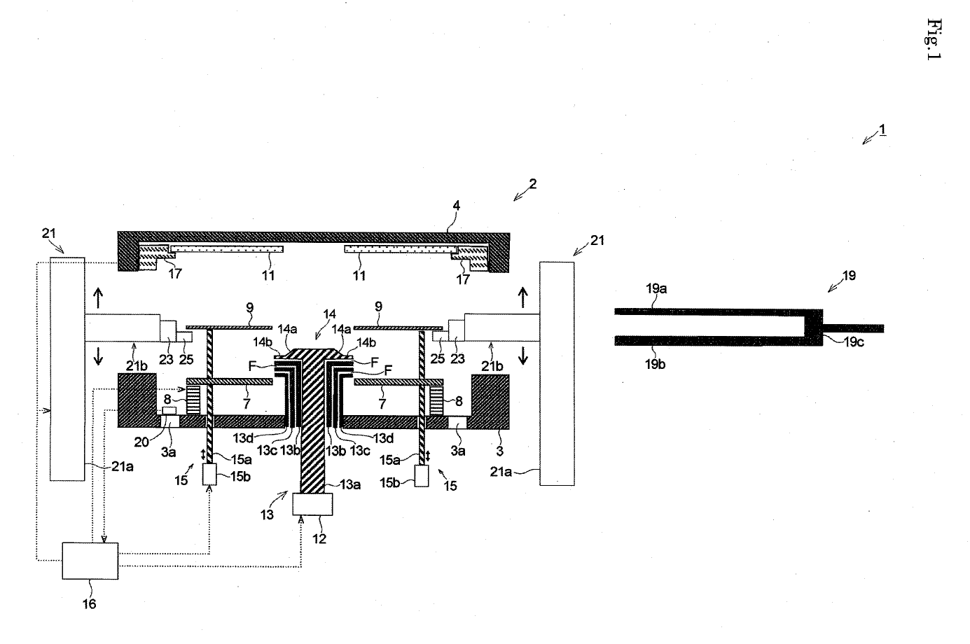

As illustrated in FIG. 1, a vapor phase growth apparatus 1 according to an embodiment of the present invention includes a chamber 2, which serves as a reaction furnace during vapor phase growth, a circular plate-shaped susceptor 7 that is rotatably and detachably arranged on the chamber 2 side and is configured to hold a substrate 5 (refer to FIG. 3) on which deposition of a semiconductor thin film is carried out during a vapor phase growth method, a susceptor cover 9 configured to cover an upper surface of the susceptor 7 to protect the susceptor 7 from a raw material gas used for depositing the semiconductor thin film, a ceiling plate 11 that is detachably arranged facing the susceptor 7 and is configured to form a flow path L of the raw material gas, a nozzle portion 13 configured to support the ceiling plate 11 and to supply the raw material gas, an upthrust ascent/descent mechanism 15 configured to raise and lower the susceptor cover 9 or the susceptor 7 on which the susceptor cover 9 is placed, a ceiling plate outer periphery support portion 17 on which an outer periphery portion of the ceiling plate 11 is placed, a transfer arm 19 configured to transfer in and transfer out the susceptor 7, the susceptor cover 9, and the ceiling plate 11, a temporary placement apparatus 21 configured to temporarily hold the susceptor 7, the susceptor cover 9, and the ceiling plate 11, and a control unit 16 configured to control operation of the nozzle portion 13, the upthrust ascent/descent mechanism 15, the ceiling plate outer periphery support portion 17, the transfer arm 19, and the temporary placement apparatus 21.

Each of these parts will now be described in more detail.

### Chamber

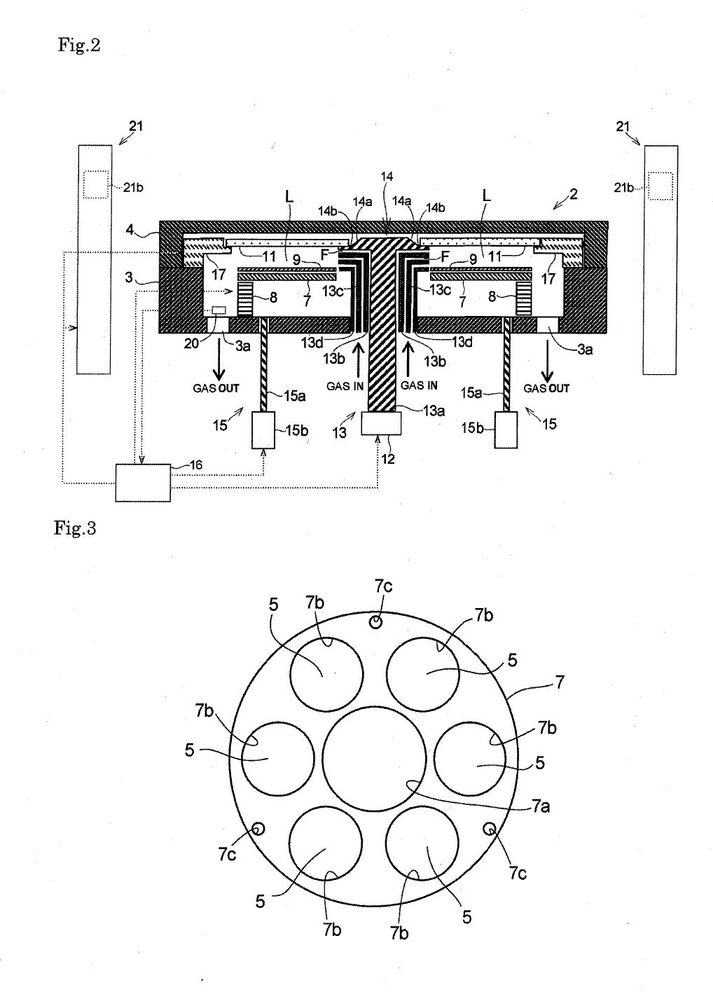

As illustrated in FIG. 2, the chamber 2 has a cylindrical shape with a flattened outline and both ends closed. The chamber 2 can be vertically divided into a chamber main body 3 having a bottomed cylindrical shape and a chamber cover 4 having a bottomed cylindrical shape which covers an open side of the chamber main body 3.

The chamber main body 3 is fixedly provided with the open side facing up. The chamber cover 4 is provided so that it can be hoisted above and below the chamber main body 3 with the open side facing down.

As illustrated in FIG. 2, the chamber main body 3 and the chamber cover 4 form a hermetically closed cylindrical shape when the chamber cover 4 is lowered and the open portions are aligned with each other, thereby forming a reaction furnace for depositing a semiconductor thin film on the substrate 5.

Stainless steel having excellent corrosion resistance may be used as the material for the chamber main body 3 and the chamber cover 4.

Note that although an example is described above in which the chamber cover 4 is moved only in a vertical direction, the chamber cover 4 may also be moved to a predetermined position in the vertical direction and moved in a horizontal direction.

### Susceptor

As illustrated in the plan view of FIG. 3, the susceptor 7 forms a circular plate shape having an open portion 7a in its center through which an upper portion of the nozzle portion 13 can be inserted. Further, the susceptor 7 is detachably and rotatably arranged on a susceptor rotation mechanism 8 provided in the chamber main body 3 (refer to FIGS. 1 and 2).

A plurality of substrate placement portions 7b on which the substrate 5 on which a thin film is to be formed is placed are provided in equal intervals in a circumferential direction around the open portion 7a. Note that FIG. 3 illustrates a state in which the substrate 5 is placed on the substrate placement portions 7b.

Three through holes 7c are provided on an outer periphery portion of the susceptor 7. The through holes 7c allow the upthrust rods 15a (described in detail below) of the upthrust ascent/descent mechanism 15 to pass through.

Carbon may be used for the material of the susceptor 7, for example. Further, the material of the substrate 5 may be selected based on the material of the semiconductor thin film to be deposited.

Susceptor Cover

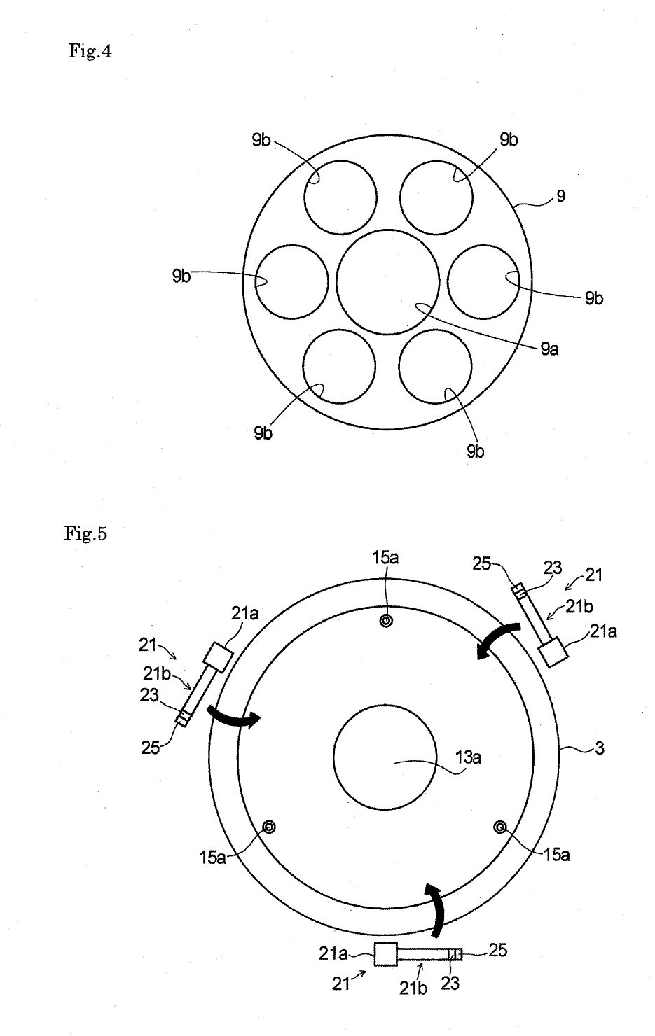

As illustrated in the plan view of FIG. 4, the susceptor cover 9 forms a circular plate shape having almost the same shape as the susceptor 7 in planar view. The susceptor cover 9 has an open portion 9a in its center through which an upper portion of the nozzle portion 13 can be inserted, and a plurality of open portions 9b around the open portion 9a.

The susceptor cover 9, which is placed on the susceptor 7, is configured to protect the susceptor 7 from contamination, oxidation and the like by the raw material gas. When the susceptor cover 9 is placed on the susceptor 7, an upper surface of the substrate 5 placed on the substrate placement portions 7b of the susceptor 7 is flush with an upper surface of the susceptor cover 9. A flow path L of the raw material gas is formed by these surfaces and a lower surface of the ceiling plate 11. Note that quartz, for example, may be used for the material of the susceptor cover 9.

### Ceiling Plate

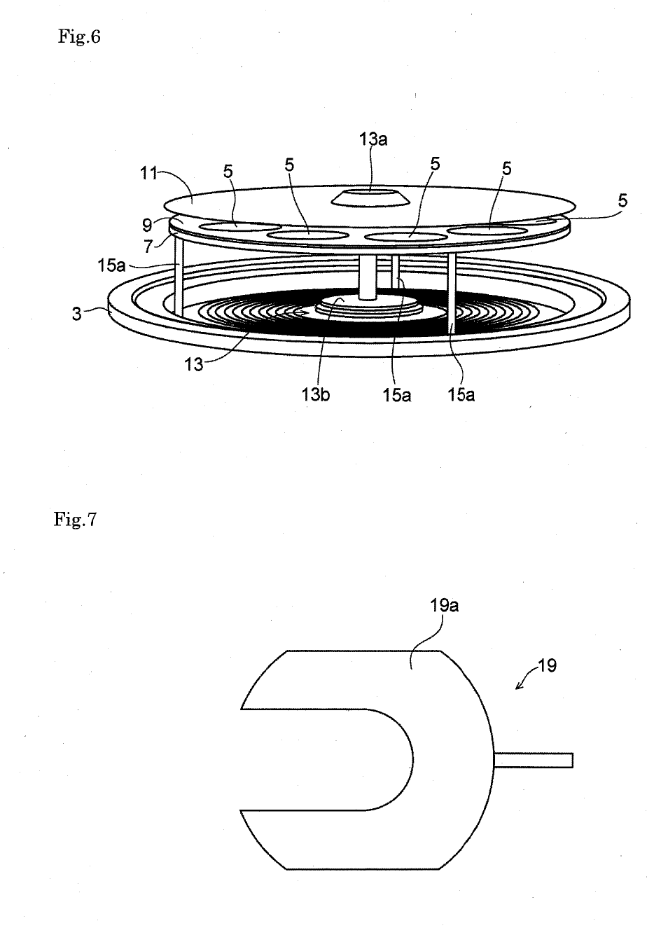

As illustrated in FIGS. 2 and 6, the ceiling plate 11 is formed from a circular plate having an open portion 11a (refer to FIG. 1) in its center through which a convex portion 14 of the nozzle portion 13 (described below) can be inserted.

FIGS. 2 and 6 illustrate a state in which the convex portion 14 of the nozzle portion 13 is inserted in the open portion 11a of the ceiling plate 11, and the ceiling plate 11 is placed and supported in the center of the nozzle portion 13.

As described above, when the ceiling plate 11 is placed on the nozzle portion 13, the flow path L of the raw material gas for depositing the semiconductor thin film is formed by the lower surface of the ceiling plate 11 and the upper surface of the susceptor cover 9 (refer to FIG. 2). At this point, the ceiling plate 11 abuts the nozzle portion 13 under its own weight (without any gap with the ceiling plate 11), thereby preventing the leakage of the raw material gas from the flow path L.

Note that quartz, for example, may be used for the material of the ceiling plate 11.

### Nozzle Device

The nozzle portion 13, which is arranged in the center of the chamber main body 3, is configured to supply the raw material gas to the flow path L of the raw material gas.

As illustrated in FIG. 1, the nozzle portion 13 includes an upthrust nozzle 13a capable of moving in a vertical direction, and a plurality of nozzle wall members (a fixed nozzle wall member 13b, a fixed nozzle wall member 13c, and a fixed nozzle wall member 13d) that are spaced apart at predetermined intervals in a radial direction from the upthrust nozzle 13a to form gas introduction paths F of the raw material gas.

The convex portion 14 is formed on an upper end portion of the upthrust nozzle 13a. On the convex portion 14 are formed a tapered surface 14a, whose diameter gradually narrows in the upward direction, and a placement portion 14b on which a center portion of the ceiling plate 11 is placed.

When the ceiling plate 11 is placed on the placement portion 14b, the position of the ceiling plate 11 can be prevented from deviating in the horizontal direction by inserting the convex portion 14 in the open portion 11a.

Further, the tapered surface 14a has a function of, when the convex portion 14 is inserted in the open portion 11a of the ceiling plate 11, guiding the ceiling plate 11 to facilitate positioning in the horizontal direction of the ceiling plate 11.

Vertical movement of the upthrust nozzle 13a is carried out by a vertical movement apparatus 12 including a pulse motor and the like. The vertical movement apparatus 12 is capable of adjusting the vertical position of the upthrust nozzle 13a to a high degree of precision (in the order of sub-millimeters) with the pulse motor and the like.

The upthrust nozzle 13a can adjust the vertical position of the ceiling plate 11 by moving vertically in a state in which the ceiling plate 11 is supported by the placement portion 14b. This operation enables the height of the flow path L to be adjusted to a high degree of precision.

The fixed nozzle wall member 13b is formed in a tubular shape having a larger diameter than the columnar diameter of the upthrust nozzle 13a, and one end of the fixed nozzle wall member 13b protrudes outwards.

Further, the fixed nozzle wall member 13c is formed in a tubular shape having a larger diameter than the fixed nozzle wall member 13b, and one end of the fixed nozzle wall member 13c protrudes outwards in the same manner as the fixed nozzle wall member 13b.

In addition, the fixed nozzle wall member 13d is formed in a tubular shape having an even larger diameter than the fixed nozzle wall member 13c, and one end of the fixed nozzle wall member 13d protrudes outwards in the same manner as the fixed nozzle wall member 13b.

By telescopically arranging the upthrust nozzle 13a, the fixed nozzle wall member 13b, the fixed nozzle wall member 13c, and the fixed nozzle wall member 13d, spaces are formed between these adjacent members. These spaces form the gas introduction paths F that introduce the raw material gas into the flow path L. The raw material gas is supplied into each gas introduction path F from a raw material gas supply portion (not shown). For example, if the semiconductor thin film to be deposited is gallium nitride, an organic metal gas, ammonia gas, and a purge gas, respectively, are supplied from the raw material gas supply portions (refer to the arrow in FIG. 2).

The raw material gas supplied from the nozzle portion 13 flows through the flow path L of the raw material gas formed by the upper surface of the susceptor cover 9 and the lower surface of the ceiling plate 11 from the center toward the outer periphery of the chamber main body 3, and is discharged from a discharge port 3a provided on the outer periphery of the chamber main body 3 (refer to the arrow in FIG. 2). Consequently, a semiconductor thin film is formed on the surface of the substrate 5 placed on the susceptor 7.

Note that the material of the raw material gas is selected based on the type of the semiconductor thin film to be deposited.

The nozzle portion 13 is not limited to the configuration illustrated in FIG. 1. The nozzle portion 13 may be configured in any manner, as long as the nozzle portion 13 is capable of vertically movement while supporting the ceiling plate 11, and supplying the raw material gas to the flow path L of the raw material gas.

### Upthrust Ascent/Descent Mechanism

The upthrust ascent/descent mechanism 15 includes three upthrust rods 15a provided so that they can be arranged at the same position as each through hole 7c (refer to FIG. 3) of the susceptor 7 provided in the chamber main body 3, and ascent/descent means 15b configured to raise and lower these upthrust rods 15a (refer to FIGS. 1 and 2). Note that FIG. 5 illustrates a state in which the susceptor 7 and the like have been removed so that the bottom portion of the chamber main body 3 can be seen.

The upthrust ascent/descent mechanism 15 is configured so that, as illustrated in FIG. 6, the susceptor 7 together with the susceptor cover 9 placed on the susceptor 7 can be hoisted by thrusting up and supporting the susceptor 7 from below.

Further, the upthrust rods 15a are capable of being raised up through the through holes 7c while thrusting up and supporting only the susceptor cover 9 by measuring a rotation angle of the susceptor 7 using a rotation angle sensor 20, and positioning and raising the upthrust rods 15a so that the through holes 7c are positioned directly above the upper end of the upthrust rods 15a by rotating the susceptor 7 based on the measured rotation angle.

Thus, when raising the upthrust rods 15a, whether to thrust up the susceptor 7 together with the susceptor cover 9 or to thrust up just the susceptor cover 9 can be appropriately selected by adjusting the relative position of the upthrust rods 15a with the through holes 7c.

It is preferred that three or more of the upthrust rods 15a are arranged in equal intervals in the outer periphery direction of the susceptor 7. Such a configuration enables the susceptor 7 to be stably supported in the above-described manner.

Further, although the number of through holes 7c of the susceptor 7 is described above as being three, this number may be appropriately increased or decreased based on the number of upthrust rods 15a.

### Ceiling Plate Outer Periphery Support Portion

As illustrated in FIG. 1, the ceiling plate outer periphery support portion 17 is arranged on the outer periphery side of the ceiling plate 11 in a manner that allows the ceiling plate outer periphery support portion 17 to be attached to and detached from either one of the chamber main body 3 and the chamber cover 4. When the ceiling plate outer periphery support portion 17 is to be mounted on the chamber cover 4, the ceiling plate outer periphery support portion 17 is raised or lowered in cooperation with the raising or lowering of the chamber cover 4 during opening or closing of the chamber 2. At this stage, the outer periphery portion of the ceiling plate 11 is supported by the ceiling plate outer periphery support portion 17, so that the ceiling plate 11 is also raised or lowered.

On the other hand, when the ceiling plate outer periphery support portion 17 is to be mounted on the chamber main body 3, during opening or closing of the chamber 2, just the chamber cover 4 can be raised or lowered while the ceiling plate 11 remains placed on the ceiling plate outer periphery support portion 17.

Thus, the ceiling plate outer periphery support portion 17 is mounted on the chamber main body 3 when the ceiling plate 11 is not to be raised or lowered in conjunction with the opening or closing of the chamber 2, and is mounted on the chamber cover 4 when the ceiling plate 11 is to be raised or lowered.

### Transfer Arm

The transfer arm 19 is arranged externally to the chamber 2, and is configured to transfer at least any one, or all, of the susceptor 7, the susceptor cover 9, and the ceiling plate 11 into and out of the chamber 2.

The transfer arm 19 is formed from a plate having, as illustrated in FIG. 7, a roughly U-shape in planar view, and that, as illustrated in FIG. 1, is vertically divided into two steps. (an upper step portion 19a and a lower step portion 19b). The upper step portion 19a and the lower step portion 19b are connected by a connecting portion 19c (refer to FIG. 1) at a U-shaped curved portion.

As illustrated in FIG. 7, the upper step portion 19a and the lower step portion 19b are roughly the same size in planar view. The upper step portion 19a and the lower step portion 19b are smaller than the susceptor 7 and the susceptor cover 9. The size of the upper step portion 19a and the lower step portion 19b is set so that when susceptor 7 and the susceptor cover 9 are placed on the upper step portion 19a and the lower step portion 19b, an outer periphery portion of the susceptor 7 and the susceptor cover 9 sticks out.

Further, the upper step portion 19a and the lower step portion 19b are set to a size and a shape that allows the upper step portion 19a and the lower step portion 19b to pass through a gap among the three upthrust rods 15a when the three upthrust rods 15a are in a raised state, and be moved above the chamber main body 3.

In addition, the transfer arm 19 is configured so that when the transfer arm 19 has been moved above the chamber main body 3 with the upthrust nozzle 13a is a raised state, there is no interference between the transfer arm 19 and the upthrust nozzle 13a due to the upthrust nozzle 13a entering the inner side of the U-shaped curved portion of the transfer arm 19.

The gap between the upper step portion 19a and the lower step portion 19b, namely, the height of the connecting portion 19c, is set in consideration of the operating range of the upthrust nozzle 13a of the nozzle portion 13, the operating range of the upthrust rods 15a of the upthrust ascent/descent mechanism 15, and the shape of the temporary placement arms 21b of the temporary placement apparatus 21 (described below), so that delivery of a transfer target member is carried out smoothly between the upper step portion 19a and the lower step portion 19b of the transfer arm 19 and an upper step support portion 23 and a lower step support portion 25 of the temporary placement apparatus 21.

### Temporary Placement Apparatus

The temporary placement apparatus 21 is configured to temporarily hold at least any one, or all, of the susceptor 7, the susceptor cover 9, and the ceiling plate 11 supported above the chamber main body 3.

As illustrated in FIGS. 1, 2, and 5, the temporary placement apparatus 21 includes three support pillars 21a that are erected at equal intervals around the outer periphery of the chamber main body 3, and temporary placement arms 21b that are configured in a rod shape thrusting out in a horizontal direction from the support pillars 21a, and that are rotatably (refer to the arrow in FIG. 5) and ascendably/descendably (refer to the arrow in FIG. 1) provided in a horizontal direction about the support pillars 21a.

As illustrated in FIG. 1, a tip portion of the temporary placement arms 21b has an upper step support portion 23 positioned one step down from the upper surface of the temporary placement arms 21b, and a lower step support portion 25 positioned yet another step down from the upper step support portion 23. The gap between the upper step support portion 23 and the lower step support portion 25 is set in consideration of the height of the upper step portion 19a and the lower step portion 19b of the transfer arm 19.

By rotating all of the temporary placement arms 21b to make the tips face the center of the chamber main body 3, the ceiling plate 11 can be supported by the upper step support portion 23 of the temporary placement arms 21b, and the susceptor 7 on which the susceptor cover 9 is placed can be supported by the lower step support portion 25.

Since the temporary placement apparatus 21 has the above-described configuration, the temporary placement apparatus 21 can receive a member placed on the transfer arm 19 by, in a state in which the transfer arm 19 on which a member such as the ceiling plate 11 is placed is positioned above the chamber main body 3, raising or lowering the temporary placement arms 21b to set the upper step support portion 23 at the same height as the upper step portion 19a of the transfer arm 19 and the lower step support portion 25 at the same height as the lower step portion 19b of the transfer arm 19, and rotating each of the temporary placement arms 21b to face the center of the chamber main body 3.

Specifically, a member can be received by supporting the outer periphery portion of the ceiling plate 11 placed on the upper step portion 19a of the transfer arm 19 with the upper step support portion 23 of the temporary placement arms 21b, or by supporting the outer periphery portion of the susceptor 7 or the susceptor cover 9 placed on the lower step portion 19b of the transfer arm 19 with the lower step support portion 25 of the temporary placement arms 21b. Note that in the following description, this position of the temporary placement arms 21b is referred to as the “receiving position”.

Further, the ceiling plate 11 can be delivered to the upthrust nozzle 13a by, in a state in which the ceiling plate 11 is supported by the upper step support portion 23 of the temporary placement apparatus 21, supporting the ceiling plate 11 with the upthrust nozzle 13a by raising the upthrust nozzle 13a.

In addition, in a state in which the susceptor 7 or the susceptor cover 9 is supported on the lower step support portion 25 of the temporary placement apparatus 21, the susceptor 7 and the like can be delivered to the upthrust ascent/descent mechanism 15 by supporting the susceptor 7 and the like by raising the upthrust rods 15a of the upthrust ascent/descent mechanism 15.

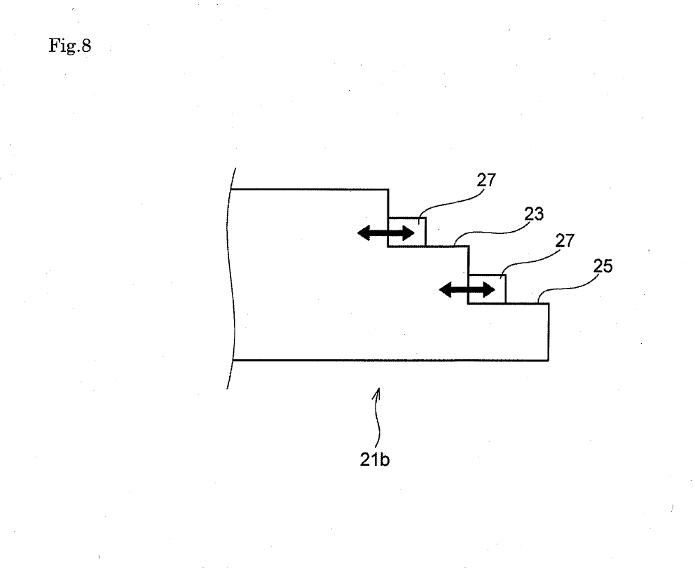

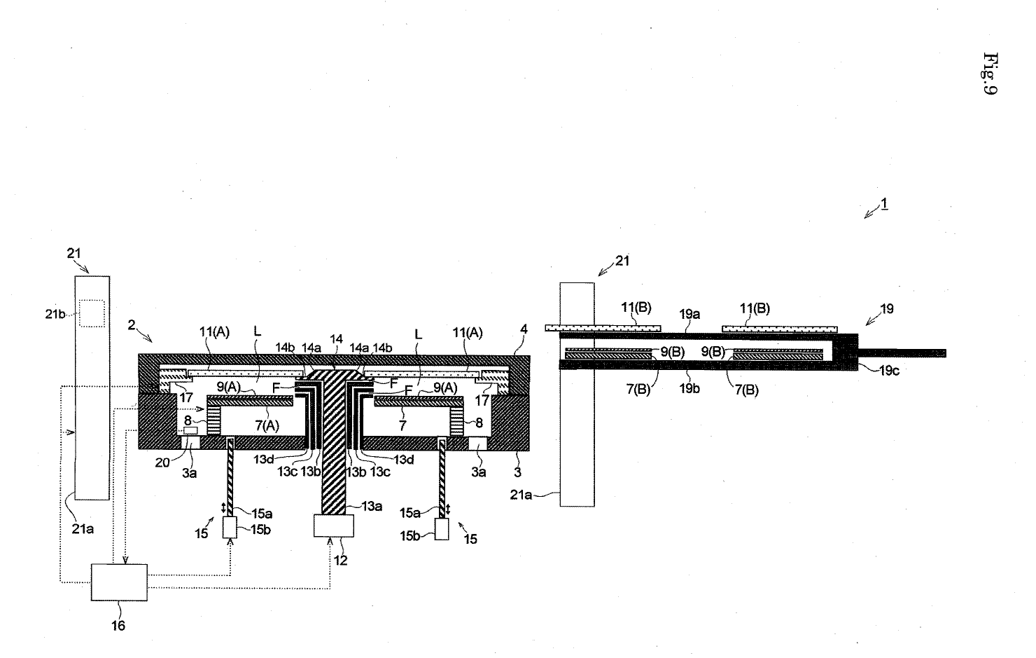

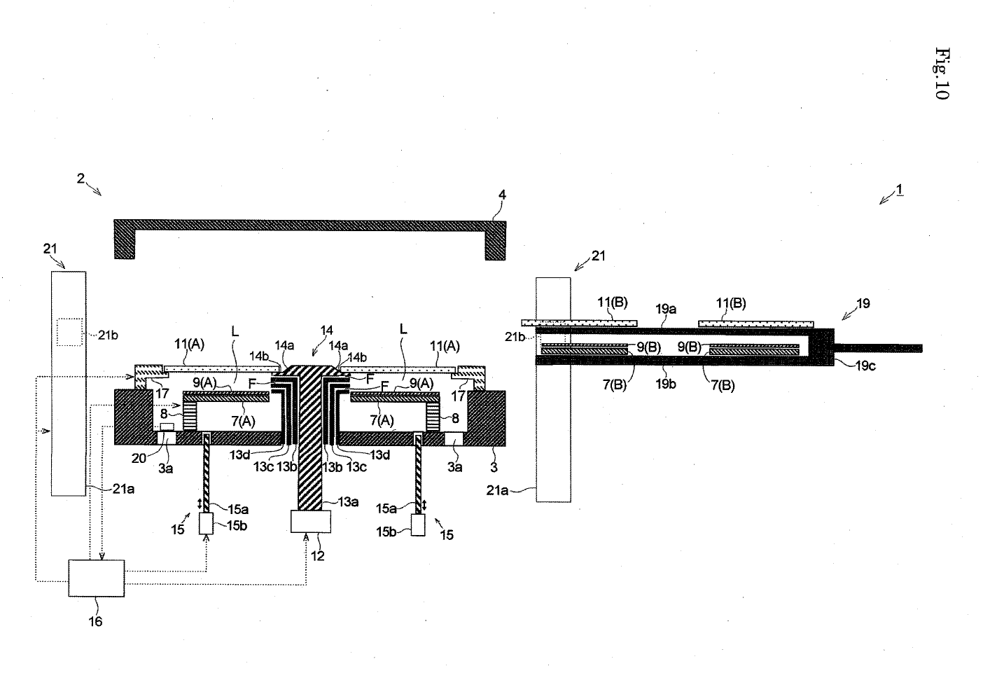

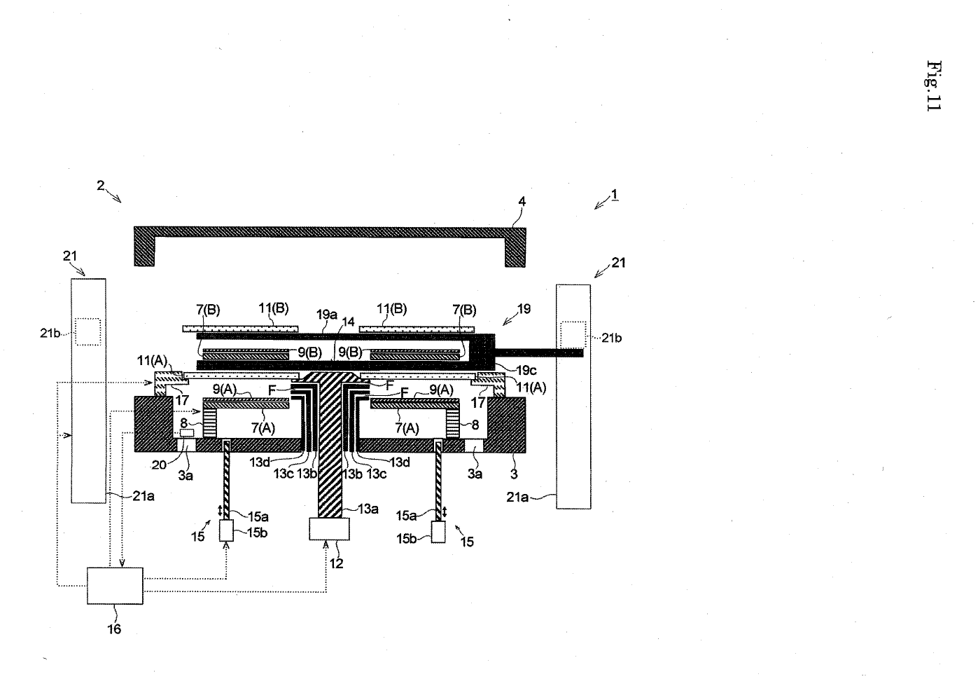

As illustrated in FIG. 8, a centering piece 27 formed from a small piece capable of protruding from a vertical wall portion in a tip direction of the temporary placement arms 21b is provided on a vertical wall portion of the upper step support portion 23 and the lower step support portion 25, respectively. If the centering piece 27 of each temporary placement arm 21b is made to protrude in a state in which members, such as the ceiling plate 11, is placed on the upper step support portion 23 or the lower step support portion 25, each member is pressed toward the center of the chamber main body 3 from three directions, so that the center of each member can be aligned (centered) with the center of the chamber main body 3. The centering piece 27 can be operated by compressed air and the like.

When closing the chamber 2, the temporary placement arms 21b are retracted out of the chamber 2.

Note that although an example of a configuration is described above in which the temporary placement apparatus 21 is provided with three temporary placement arms 21b spaced at equal intervals around the outer periphery, the arrangement and the number of temporary placement arms 21b are not limited to the above-described configuration. Any configuration may be employed as long, as the transfer target members can be stably supported.

Further, although an example is described above of the temporary placement arms 21b in which the diameter of the ceiling plate 11 is larger than the diameter of the susceptor 7 and the susceptor cover 9, the temporary placement arms 21b are not limited to such a shape, as long as the temporary placement arms 21b are capable of simultaneously supporting a plurality of members.

Note that although the temporary placement apparatus 21 is described above as being capable of receiving members such as the ceiling plate 11 from the transfer arm 19, by reversing the order, the temporary placement apparatus 21 can deliver members to the transfer arm 19.

Similarly, although the temporary placement apparatus 21 is described above as being capable of delivering members such as the ceiling plate 11 to the upthrust nozzle 13a and the upthrust ascent/descent mechanism 15, by reversing the order, the temporary placement apparatus 21 can receive members from the upthrust nozzle 13a and the upthrust ascent/descent mechanism 15.

### Control Unit

The control unit 16 is configured to control operation of the nozzle portion 13, the upthrust ascent/descent mechanism 15, the ceiling plate outer periphery support portion 17, the transfer arm 19, and the temporary placement apparatus 21. Specifically, for example, the control unit 16 controls operation of the vertical movement apparatus 12 that raises and lowers the upthrust nozzle 13a, controls operation of the ascent/descent means 15b that raises and lowers the upthrust rods 15a of the upthrust ascent/descent mechanism 15, controls mounting of the ceiling plate outer periphery support portion 17 onto the chamber main body 3 or the chamber cover 4, controls raising and lowering of the chamber cover 4, controls a transfer operation of the transfer arm 19 into and out of the chamber 2, and controls movement of the temporary placement arms 21b of the temporary placement apparatus 21, and controls operation of the centering piece 27. These control operations, are carried out by executing a program provided in the control unit 16. Note that the arrangement location of the control unit 16 is not especially limited, as long as operation of the nozzle portion 13, the upthrust ascent/descent mechanism 15, the ceiling plate outer periphery support portion 17, the transfer arm 19, and the temporary placement apparatus 21 can be controlled.

An example of a method of transferring members (ceiling plate 11, susceptor cover 9, susceptor 7) using the thus-configured vapor phase growth apparatus 1 according to the present embodiment is now described along with operation of the vapor phase growth apparatus 1.

Five combinations of the transfer target members of the vapor phase growth apparatus 1 are described: (1) the susceptor 7, the susceptor cover 9, and the ceiling plate 11; (2) the susceptor 7 and the susceptor cover 9; (3) the susceptor cover 9 and the ceiling plate 11; (4) the susceptor cover 9 only; and (5) the ceiling plate 11 only.

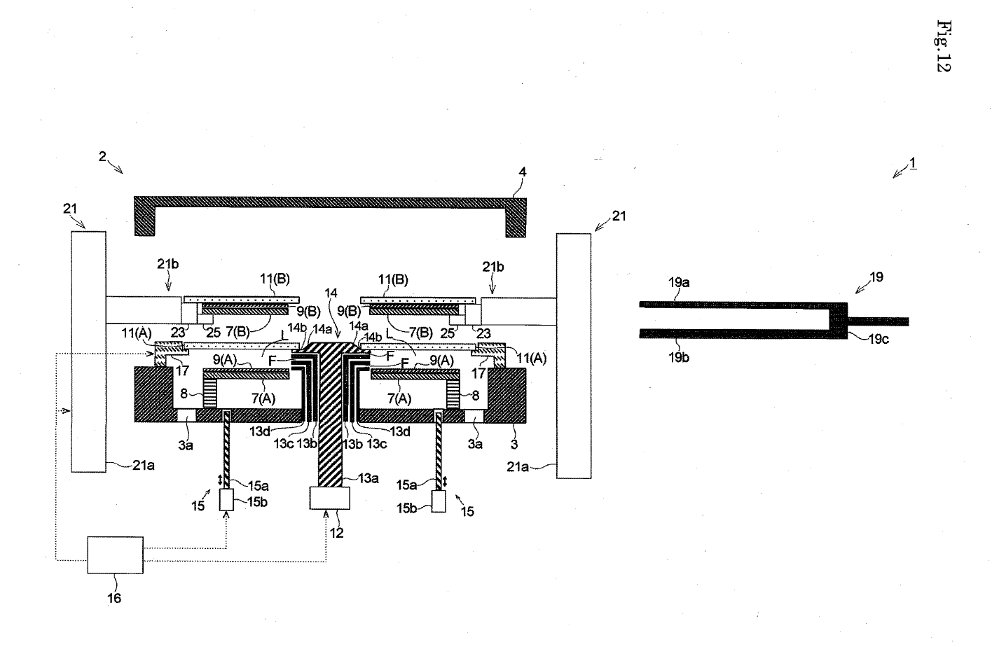

As an example, a method of replacing a used susceptor 7, susceptor cover 9, and ceiling plate 11 that were used in a vapor phase growth treatment with pre-use parts is described below with reference to FIGS. 9 to 19 along with a description of the above-described transfer method (1), in which the susceptor 7, the susceptor cover 9, and the ceiling plate 11 are the transfer targets.

Note that in the following description and the drawings, to distinguish between the used and pre-use susceptor 7, susceptor cover 9, and ceiling plate 11, used parts are denoted with the letter (A) (i.e., susceptor 7(A), susceptor cover 9(A), and ceiling plate 11(A)), and pre-use parts are denoted with the letter (B) (i.e., susceptor 7(B), susceptor cover 9(B), and ceiling plate 11(B)).

Operation of the constituent elements of the vapor phase growth apparatus 1 in each step is controlled by the control unit 16.

FIG. 9 illustrates a state after a vapor phase growth treatment, in which the chamber cover 4 is in contact with the chamber main body 3, and the chamber 2 is closed.

The used susceptor 7(A) is supported on the susceptor rotation mechanism 8 in a state in which the substrate 5 is placed on the substrate placement portions 7b. Further, the susceptor cover 9(A) is placed on the susceptor 7(A).

The ceiling plate 11(A) is supported on the placement portion 14b of the upthrust nozzle 13a. The upper end surface of the upthrust rods 15a is positioned lower down than the susceptor 7(A). The ceiling plate outer periphery support portion 17 is mounted on the chamber cover 4.

The transfer arm 19 and the temporary placement arms 21b are retracted out of the chamber 2. A pre-use ceiling plate 11(B) is placed on the upper step portion 19a of the transfer arm 19, and a pre-use susceptor 7(B) with a susceptor cover 9(B) placed thereon is placed on the lower step portion 19b.

Based on the above-described state as an initial position, the following Steps 1 to 6 are performed in order.

### Step 1

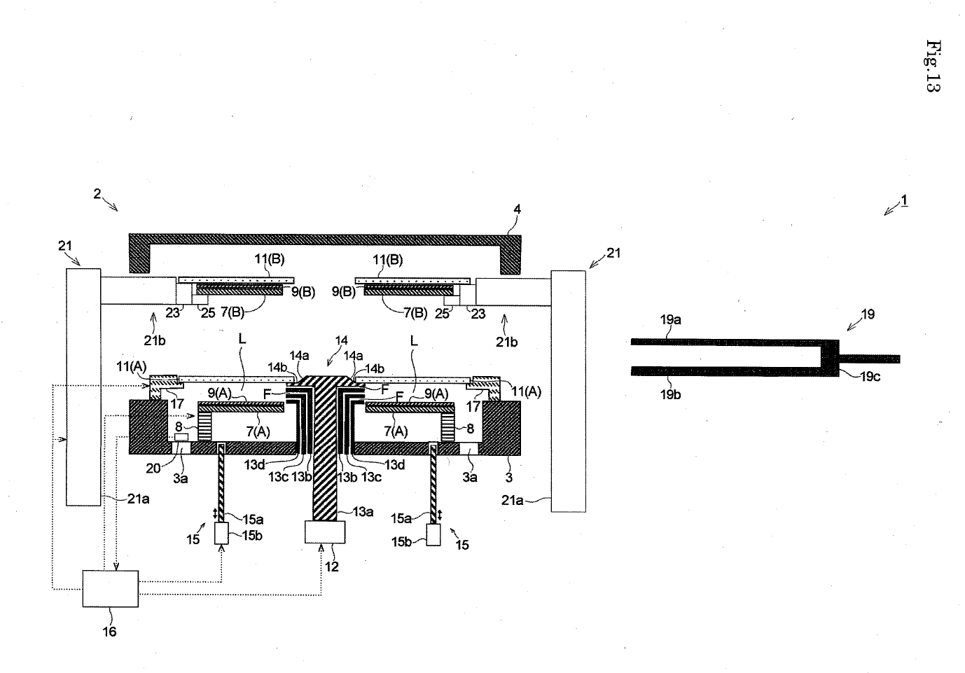

First, the ceiling plate outer periphery support portion 17 is mounted on the chamber main body 3 side, and the chamber 2 is opened by raising the chamber cover 4 from the initial position to a position higher than the upper step portion 19a of the transfer arm 19 (refer to FIG. 10). At this stage, since the ceiling plate outer periphery support portion 17 is mounted on the chamber main body 3, the ceiling plate outer periphery support portion 17 stops at the initial position while supporting the outer periphery portion of the ceiling plate 11(A).

### Step 2

Next, the transfer arm 19 is moved in the horizontal direction, and positioned above the chamber main body 3 (refer to FIG. 11).

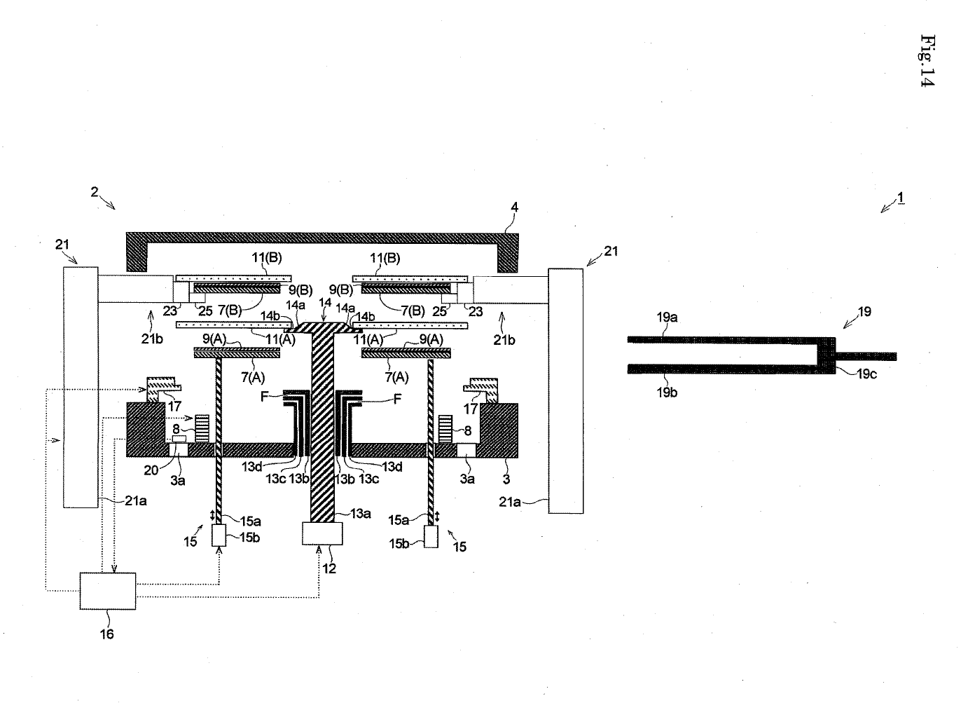

Next, the ceiling plate 11(B) is received by the temporary placement apparatus 21 by moving the temporary placement arms 21b from the initial position to the receiving position and supporting the outer periphery portion of the ceiling plate 11(B) protruding from the upper step portion 19a with the upper step support portion 23 of the temporary placement apparatus 21. Further, in conjunction with this, the susceptor 7(B) on which the susceptor cover 9(B) is placed is received by the temporary placement apparatus 21 by supporting the outer periphery portion of the susceptor 7(B) protruding from the lower step portion 19b with the lower step support portion 25. After the transfer arm has delivered each of these members, the transfer arm is retracted out of the chamber (refer to FIG. 12).

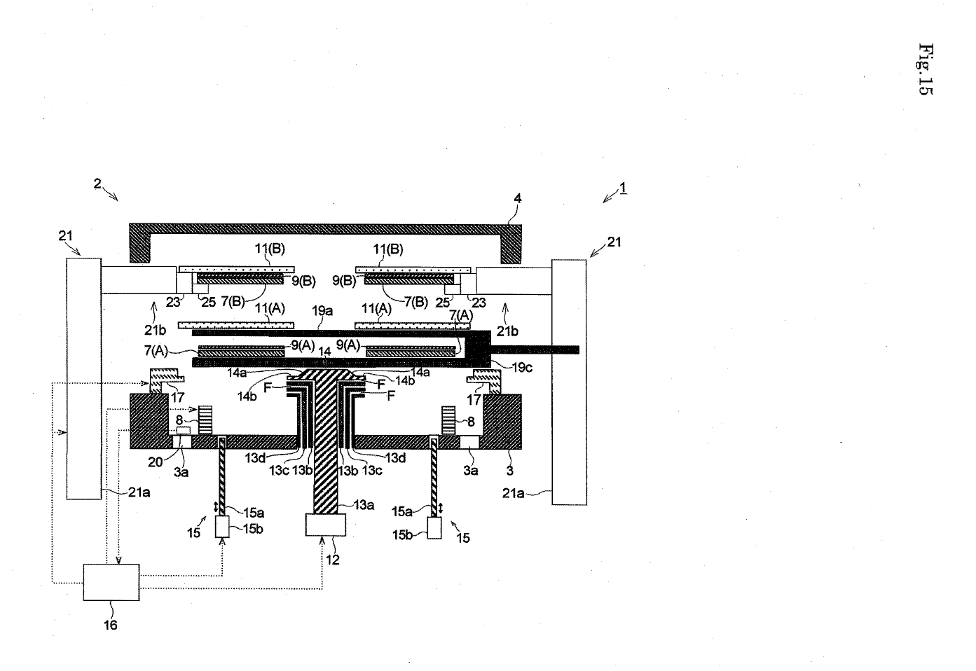

Then, the temporary placement arms 21b of the temporary placement apparatus 21 are raised, and the pre-use ceiling plate 11(B), susceptor 7(B), and susceptor cover 9(B) are retracted upward (refer to FIG. 13).

By performing this operation, the ceiling plate 11(B), the susceptor 7(B), and the susceptor cover 9(B) can be temporarily placed above the Chamber main body 3. Consequently, there is no need to separately provide a location for temporary placement, and thus the size of the vapor phase growth apparatus can be reduced.

After each member has been received by the temporary placement apparatus 21, the centering piece 27 of the upper step support portion 23 and the lower step support portion 25 is operated, and the ceiling plate 11(B) and the susceptor 7(B) are centered.

### Step 3

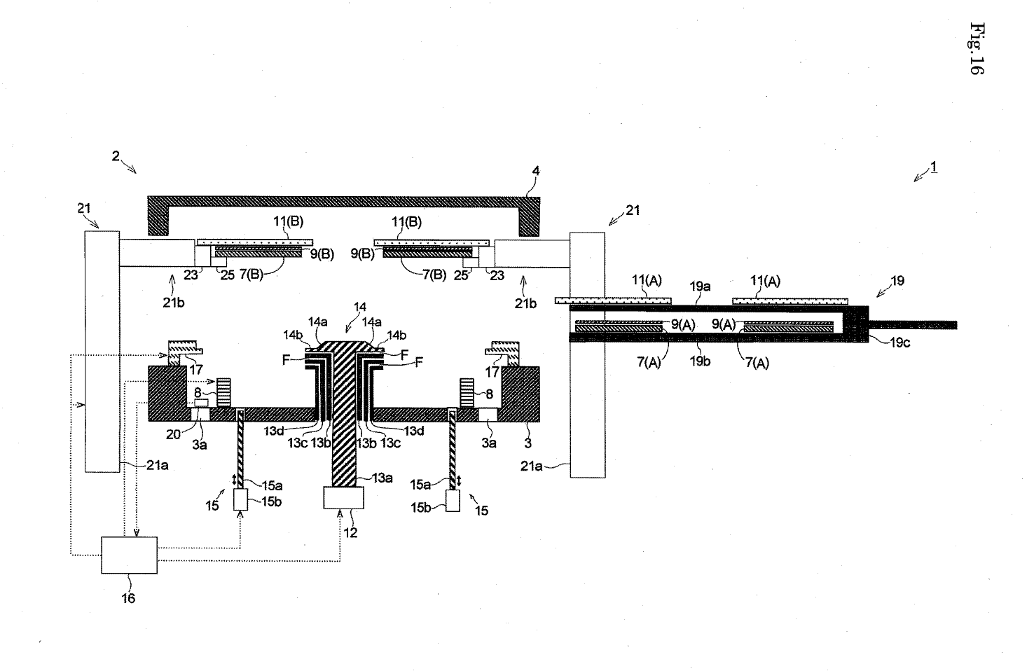

Next, the used ceiling plate 11(A) is thrust up to the height of the upper step portion 19a of the transfer arm 19 by raising the upthrust nozzle 13a from the initial position, and the used susceptor 7(A) is thrust up to the height of the lower step portion 19b of the transfer arm 19 by raising the upthrust rods 15a of the upthrust ascent/descent mechanism 15 from the initial position (refer to FIG. 14).

When raising the upthrust rods 15a, if the through holes 7c of the susceptor 7 are directly above the upthrust rods 15a, the susceptor 7(A) is rotated using the susceptor rotation mechanism 8 to offset the position of the through holes 7c so that the upthrust rods 15a do not pass through the through holes 7c.

By performing this operation, the susceptor 7(A) can be thrust up together with the susceptor cover 9.

### Step 4

Next, the transfer arm 19 is moved horizontally to position the upper step portion 19a of the transfer arm 19 between the thrust-up used ceiling plate 11(B) and the susceptor cover 9(B) and to position the lower step portion 19b of the transfer arm 19 below the thrust-up used susceptor 7(B).

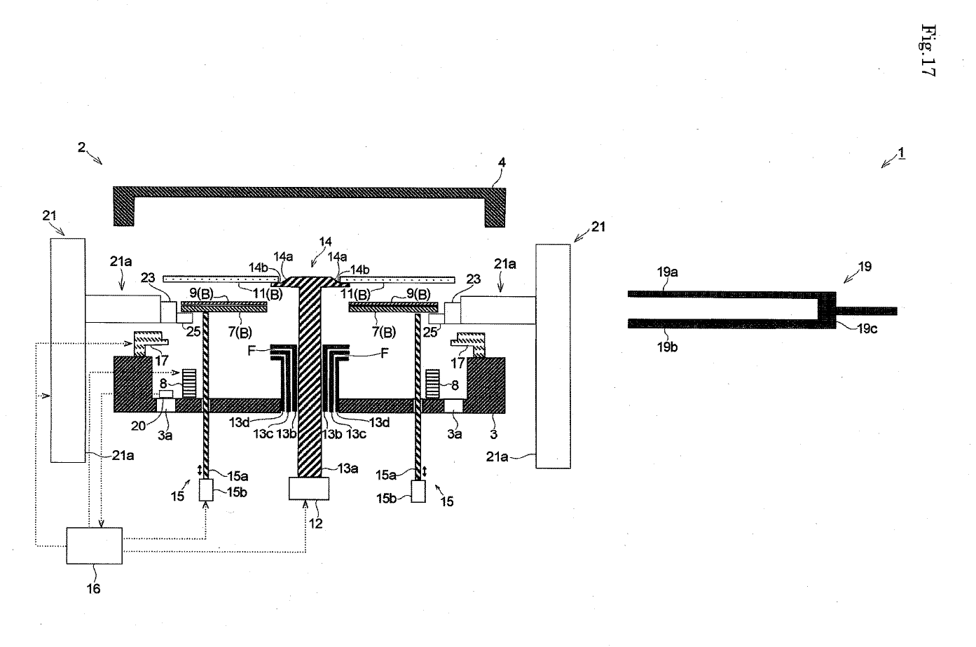

Then, by lowering the upthrust nozzle 13a and the upthrust rods 15a, the used ceiling plate 11(B) can be placed on the upper step portion 19a of the transfer arm 19, and the used susceptor 7(B) and susceptor cover 9(B) can be placed on the lower step portion 19b of the transfer arm 19. In this manner, the ceiling plate 11(B) and the like are delivered to the transfer arm 19. The upthrust nozzle 13a and the upthrust rods 15a are lowered in this state, and returned to the initial position (refer to FIG. 15).

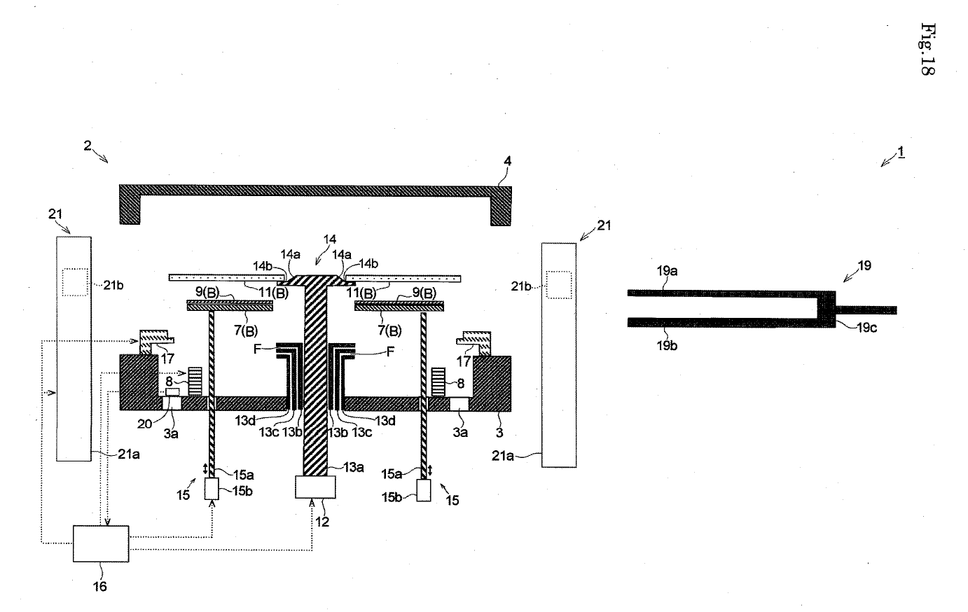

Then, the transfer arm 19 is moved out of the chamber 2. Consequently, the used ceiling plate 11(A) and the like are transferred out of the chamber 2 (refer to FIG. 16). After the transfer, the substrate 5 on which vapor phase growth was performed that is placed on the susceptor 7(A) can be recovered, and the transferred ceiling plate 11(A) and the like can be washed.

### Step 5

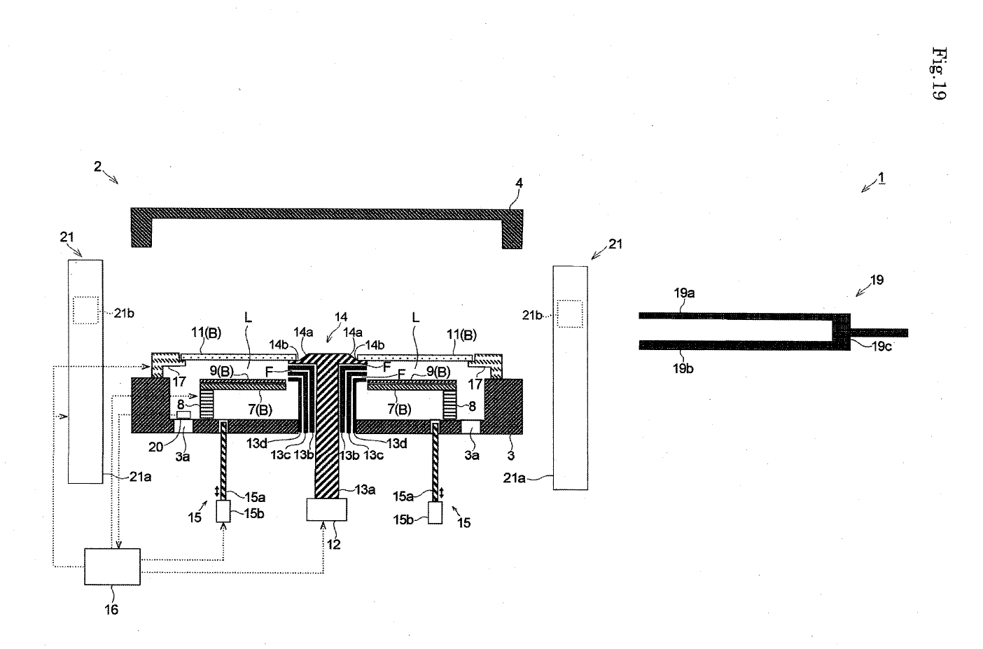

Next, by lowering the temporary placement arms 21b of the temporary placement apparatus, the pre-use ceiling plate 11(B) and the like that were retracted above are lowered, and the upthrust nozzle 13a and the upthrust rods 15a are raised. Consequently, the ceiling plate 11(B) is placed on the upthrust nozzle 13a, and the susceptor 7(B) on which the susceptor cover 9(B) is arranged is placed on the upthrust rods 15a (refer to FIG. 17).

At this time, since the ceiling plate 11(B) has been centered in advance, the positioning of the ceiling plate 11(B) on the upthrust nozzle 13a can be accurately carried out.

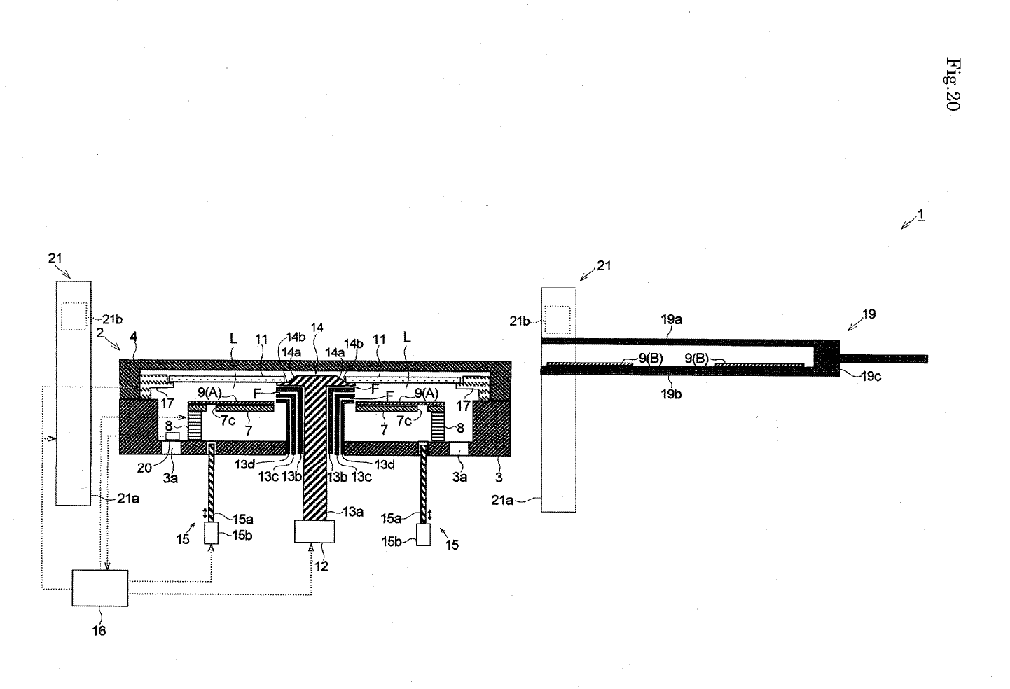

Then, the temporary placement arms 21b of the temporary placement apparatus 21 are rotated and made to retract out of the chamber 2 (refer to FIG. 18).

### Step 6

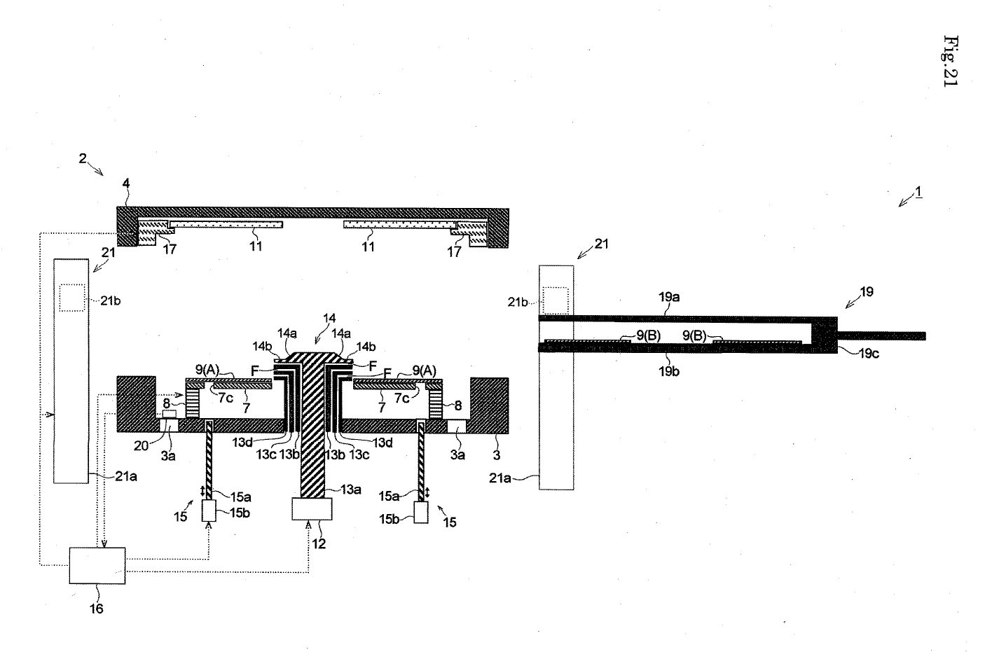

Next, the upthrust rods 15a are lowered, and the susceptor 7(B) is rotatably placed on the susceptor rotation mechanism 8. Further, the upthrust nozzle 13a is moved downward, and the outer periphery portion of the ceiling plate 11(B) is fitted into a concave portion of the ceiling plate outer periphery support portion 17 (refer to FIG. 19). Consequently, a flow path L of the raw material gas is formed by the lower surface of the ceiling plate 11 and the upper surface of the susceptor cover 9(B). At this point, the ceiling plate 11 abuts the upthrust nozzle 13a without any gap, thereby allowing vapor phase growth to be carried out without the raw material gas leaking from the flow path L.

Thus, although the pre-use ceiling plate 11(B) and the like are returned to the same position as the initial position by lowering the upthrust nozzle 13a and the upthrust rods 15a, since the susceptor 7(B) (susceptor cover 9(B)) is at this point centered and placed on the upthrust rods 15a, the susceptor 7(B) can be accurately arranged in the chamber main body 3.

As described above, since the position of the upthrust nozzle 13a can be precisely adjusted, the height of the flow channel L can be set to a predetermined height by adjusting the position of the ceiling plate 11. Therefore, the flow of the raw material gas can be set at a fixed level by setting the height of the flow channel L to the same height every time, which enables the reproducibility of the vapor phase growth to be increased (refer to FIG. 19).

By performing the above operations, replacement of the susceptor 7, the susceptor cover 9, and the ceiling plate 11 is completed. Then, by lowering the chamber cover 4 to close the chamber 2, a vapor phase growth treatment can be carried out again.

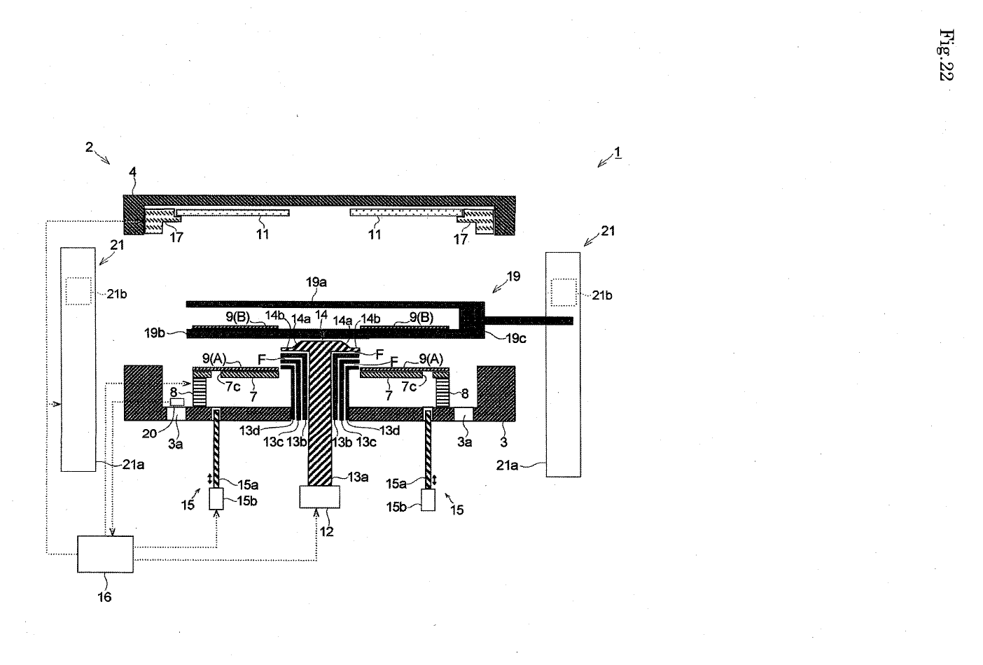

Further, as another example, a case in which only the susceptor cover 9 is the transfer target (the above-mentioned (4)) will be described with reference to FIGS. 20 to 30.

The initial state is the same as in the above-described case in which the susceptor 7, the susceptor cover 9, and the ceiling plate 11 are the transfer targets (the above-mentioned (1)), except for the fact that only the pre-use susceptor cover 9(B) is placed on the lower step portion 19b of the transfer arm 19 (refer to FIG. 20).

Based on the above-described state as an initial position, the following Steps 1 to 6 are performed in order.

### Step 1

First, with the ceiling plate outer periphery support portion 17 still mounted on the chamber cover 4, the chamber 2 is opened by raising the chamber cover 4 to a position higher than the upper step portion 19a of the transfer arm 19 (refer to FIG. 21). At this stage, since the ceiling plate outer periphery support portion 17 is mounted on the chamber cover 4, the ceiling plate outer periphery support portion 17 and the ceiling plate 11 are raised by raising the chamber cover 4.

### Step 2

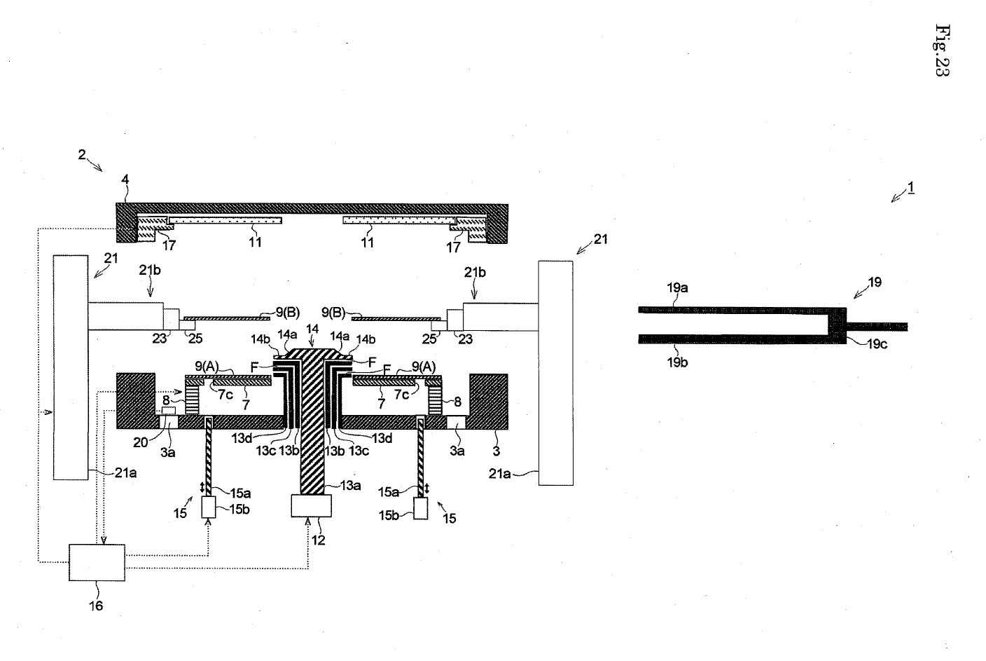

Next, the transfer arm 19 is moved in the horizontal direction, and positioned above the chamber main body 3 (refer to FIG. 22).

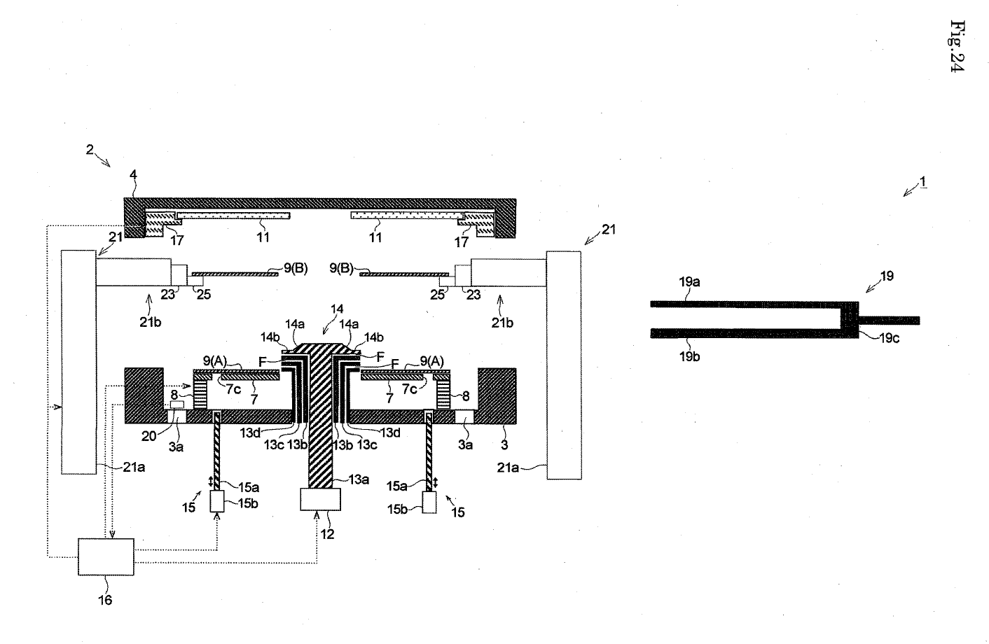

Next, the susceptor cover 9(B) placed on the lower step portion 19b of the transfer arm 19 is received by the lower step support portion 25 by moving the temporary placement arms 21b of the temporary placement apparatus 21 from the initial position to the receiving position. After the transfer arm 19 has delivered the susceptor cover 9(B), the transfer arm 19 is retracted out of the chamber 2 (refer to FIG. 23).

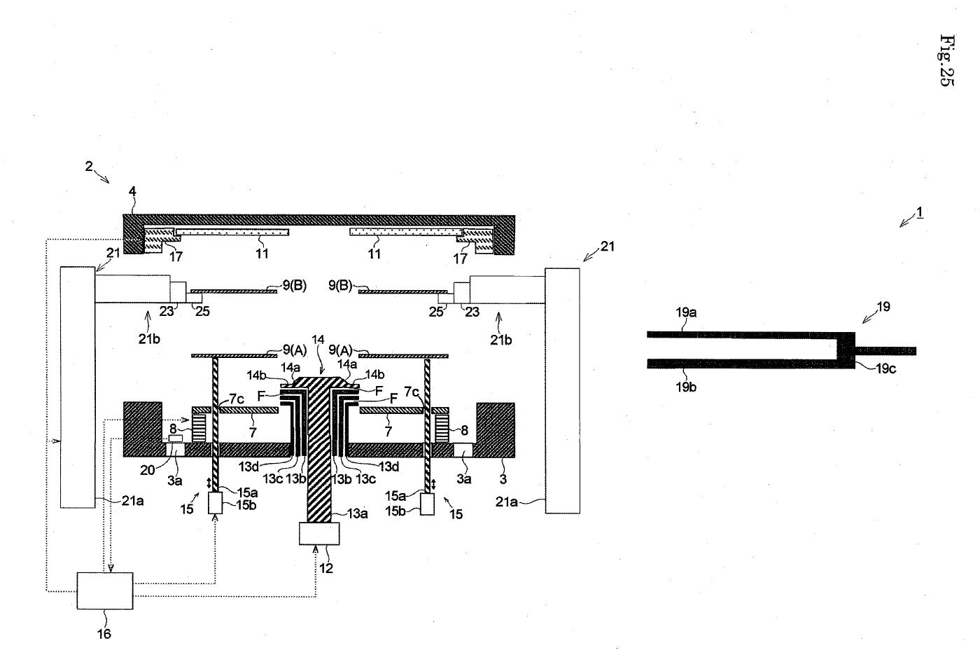

Then, the temporary placement arms 21b are raised, and the pre-use susceptor cover 9(B) is retracted upward (refer to FIG. 24).

After the susceptor cover 9(B) has been received by the temporary placement apparatus 21, the centering piece 27 of the lower step support portion 25 is operated while holding with the temporary placement apparatus 21 to center the susceptor cover 9(B).

### Step 3

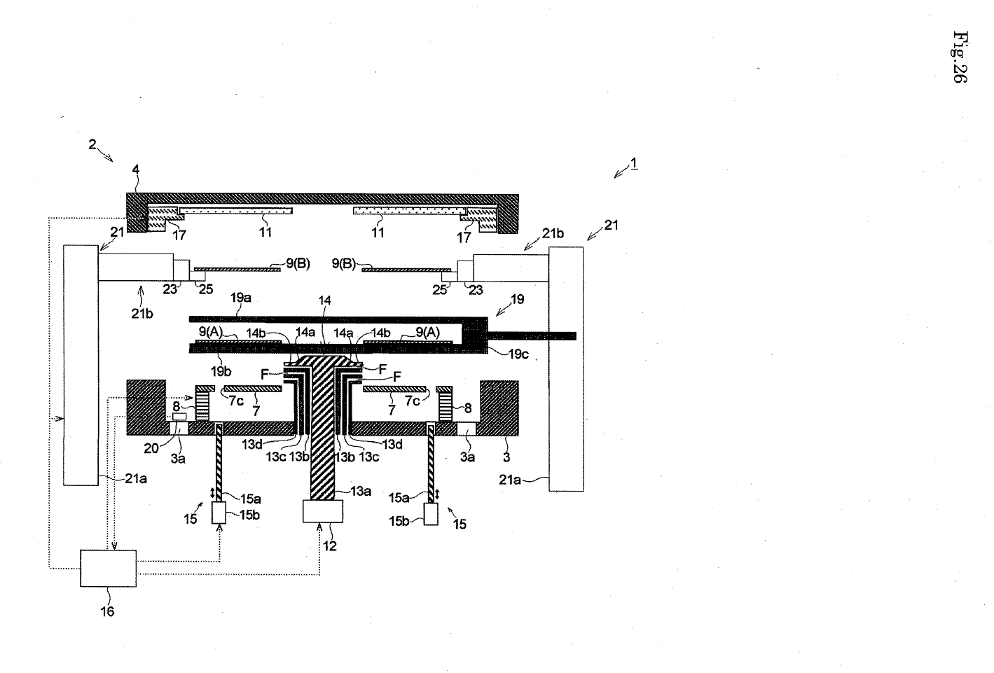

Next, the upthrust rods 15a of the upthrust ascent/descent mechanism 15 are raised and made to pass through the through holes 7c of the susceptor 7, and only the used susceptor cover 9(A) is thrust up to the height of the lower step portion 19b of the transfer arm 19 (refer to FIG. 25). At this stage, if the through holes 7c of the susceptor 7 are not at a position where the upthrust rods 15a pass through, the susceptor 7 is rotated using the susceptor rotation mechanism 8 to align the position of the through holes 7c so that the upthrust rods 15a pass through the through holes 7c.

### Step 4

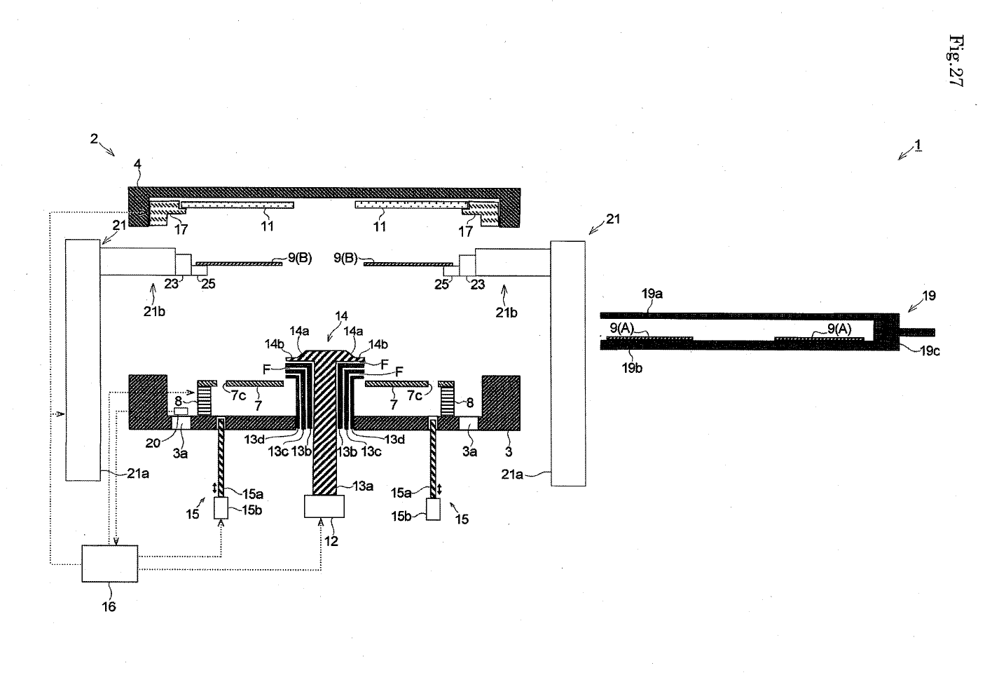

Next, the transfer arm 19 is moved horizontally and positioned beneath the used susceptor cover 9(A). Then, by lowering the upthrust rods 15a, the used susceptor cover 9(A) is placed on the lower step portion 19b of the transfer arm 19. In this manner, the used susceptor cover 9(A) is delivered to the transfer arm 19. The upthrust rods 15a is lowered in this state, and returned to the initial position (refer to FIG. 26).

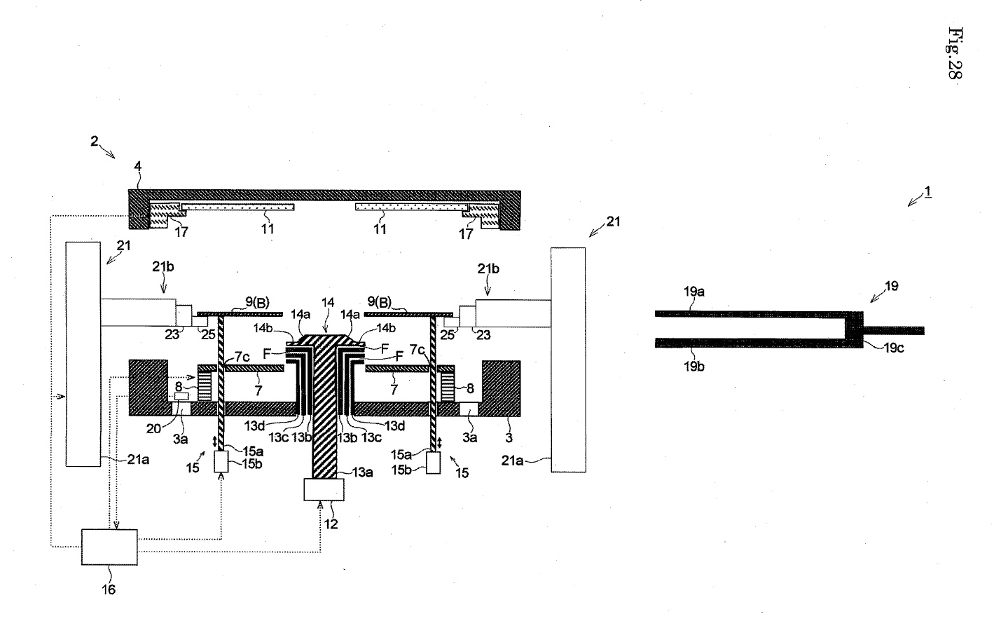

Then the transfer arm 19 is moved out of the chamber 2. Consequently, the used susceptor cover 9(A) is transferred out of the chamber 2 (refer to FIG. 27).

### Step 5

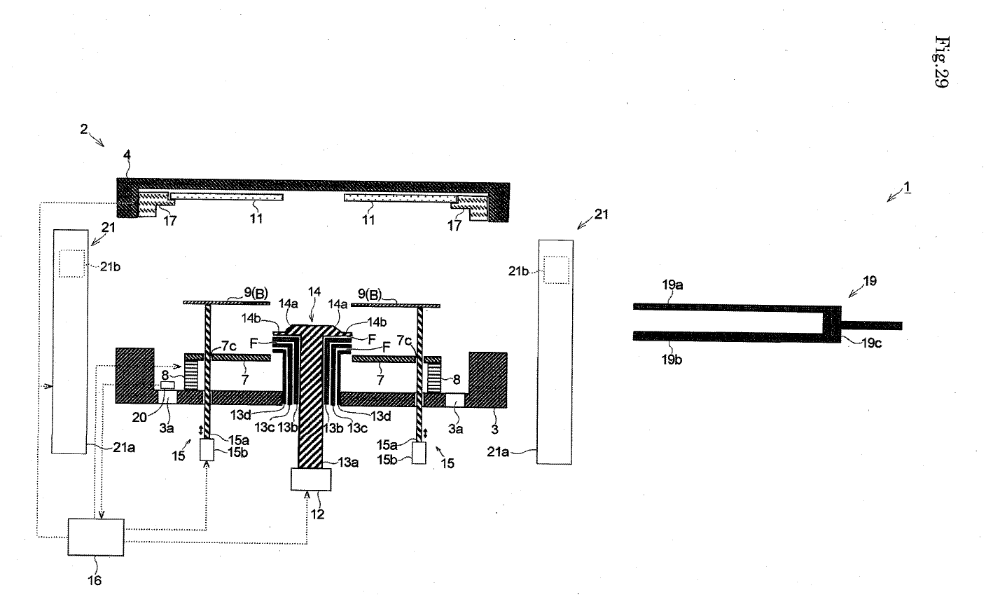

Next, by lowering the temporary placement arms 21b of the temporary placement apparatus, the pre-use susceptor cover 9(B) that had been retracted above is lowered, and the upthrust rods 15a are raised, so that the susceptor cover 9(B) is supported by the upthrust rods 15a (refer to FIG. 28).

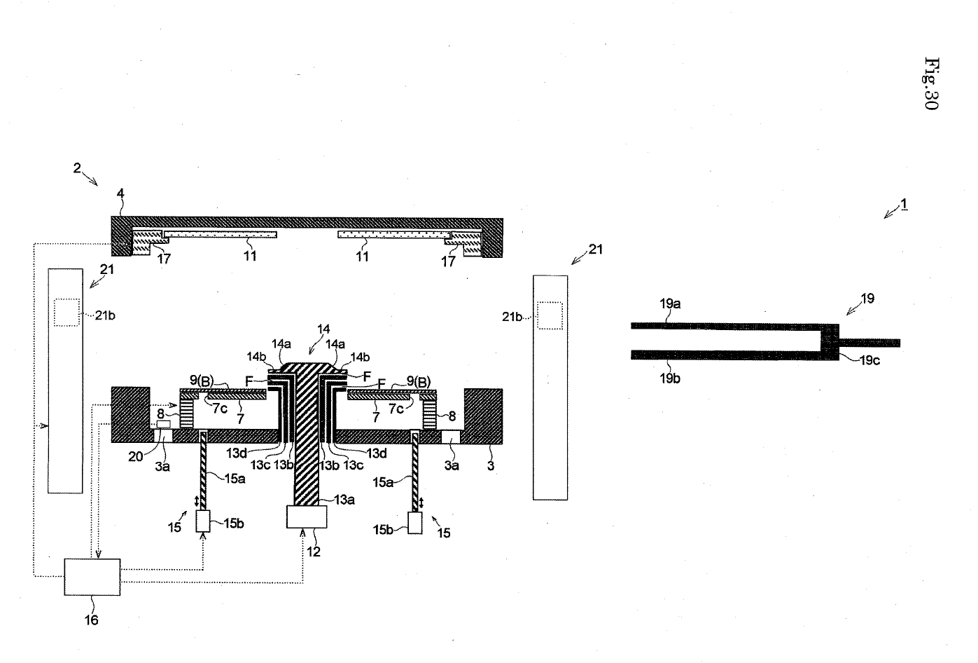

Then, the temporary placement arms 21b of the temporary placement apparatus 21 are rotated and retracted out of the chamber 2 (refer to FIG. 29).

### Step 6

Next, the pre-use susceptor cover 9(B) is returned to the same position as the initial position by lowering the upthrust rods 15a. Consequently, the susceptor cover 9(B) is placed on the susceptor 7 (refer to FIG. 30).

By performing the above operations, replacement of the susceptor cover 9 is completed. Then, by lowering the chamber cover 4 to close the chamber 2, a vapor phase growth treatment can be carried out again.

Thus, in the present embodiment, a high-productivity, compact vapor phase growth apparatus can be provided by including a chamber 2 configured to serve as a reaction furnace during vapor phase growth, a susceptor 7 formed from a circular plate that is detachably arranged on the chamber 2 side and is configured to hold a substrate, a susceptor cover 9 that covers an upper surface of the susceptor 7 and is configured to protect the susceptor 7 from a raw material gas, a ceiling plate 11 that is detachably arranged facing the susceptor cover 9 and is configured to form a flow path of the raw material gas, and a temporary placement apparatus 21 capable of temporarily holding at least one or all of the susceptor 7, the susceptor cover 9, and the ceiling plate 11 at the same position as the chamber 2 in a planar view.

Further, in the present embodiment, by including the upthrust ascent/descent mechanism 15 configured to ascendably/descendably support the susceptor 7 or the susceptor cover 9 from below, delivery of the susceptor 7 and the susceptor cover 9 to the transfer arm 19 can be achieved with a single mechanism. Therefore, other mechanisms do not need to be separately provided, which allows the size of the vapor phase growth apparatus to be reduced.

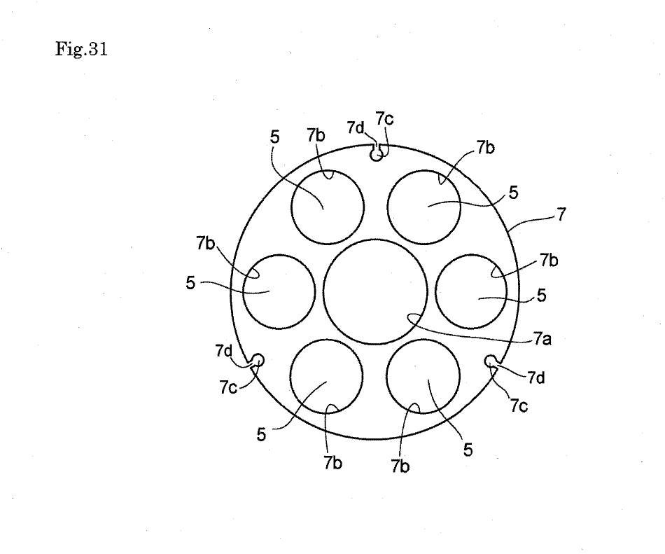

Note that although the susceptor 7 is described above as having circular through holes 7c, the shape of the through holes 7c is not limited as long as the upthrust rods 15a can pass through the through holes 7c. For example, as illustrated in FIG. 31, the susceptor 7 may be configured so that the through holes 7c are in communication with notches 7d that are cut from the outer periphery portion of the susceptor 7 in a radial direction of the susceptor 7 from the through holes 7c. By configuring in this manner, during a vapor phase growth treatment, the susceptor 7 can be prevented from breaking and cracks can be prevented from forming in the susceptor 7 even in a situation in which a temperature difference in the susceptor 7 has been produced due to the temperature in the interior of the chamber 2 increasing. Consequently, a decrease in the life of the susceptor 7 can be prevented.

Further, in the present embodiment, since the vertical position of the ceiling plate 11 can be adjusted in a state in which the ceiling plate 11 is supported by the upthrust nozzle 13a of the nozzle portion 13, the height of the flow channel L can be set to the same height every time, which enables the reproducibility of the vapor phase growth treatment to be increased.

### REFERENCE SIGNS LIST

L Flow path
F Gas introduction path
1 Vapor phase growth apparatus
2 Chamber
3 Chamber main body
3a Discharge port
4 Chamber cover
5 Substrate
7 Susceptor
7a Open portion
7b Substrate placement portion
7c Through hole
8 Susceptor rotation mechanism
9 Susceptor cover
9a Open portion
9b Open portion
11 Ceiling plate
12 Vertical movement apparatus
13 Nozzle portion
13a Upthrust nozzle
13b, 13c, 13d Fixed nozzle wall
14 Convex portion
14a Tapered surface
14b Placement portion
15 Upthrust ascent/descent mechanism
15a Upthrust rod
15b Ascent/descent means
16 Control unit
17 Ceiling plate outer periphery support portion
19 Transfer arm
19a Upper step portion
19b Lower step portion
19c Connecting portion
21 Temporary placement apparatus
21a Support pillar
21b Temporary placement arm
23 Upper step support portion
25 Lower step support portion
27 Centering piece

1. A vapor phase growth apparatus configured to supply a raw material gas onto a substrate placed in a chamber that can be vertically divided into a chamber main body and a chamber cover to cause a thin film to grow on the substrate, the vapor phase growth apparatus comprising:
a susceptor formed from a circular plate that is detachably arranged on the chamber main body side and is configured to hold the substrate;
a susceptor cover to be placed on the susceptor so as to cover a region other than a substrate holding portion of the susceptor;
a ceiling plate that is provided separated from the susceptor by a predetermined interval and faces the susceptor to form a flow path of the raw material gas; and
a temporary placement apparatus configured to temporarily place at least one of the susceptor, the susceptor cover, and the ceiling plate in a space above the chamber main body formed when the chamber has been divided.

2. The vapor phase growth apparatus according to claim 1,
wherein the temporary placement apparatus comprises one or a plurality of temporary placement arms capable of entering and exiting the space above the chamber main body, and
wherein the one or a plurality of temporary placement arms comprise at a tip thereof a temporary placement portion for temporary placement of at least one of the susceptor, the susceptor cover, and the ceiling plate.

3. The vapor phase growth apparatus according to claim 1, wherein the temporary placement apparatus comprises:
a ceiling plate temporary placement portion for temporary placement of the ceiling plate; and
a susceptor temporary placement portion for temporary placement of the susceptor on which the susceptor cover is placed or the susceptor cover.

4. The vapor phase growth apparatus according to claim 3,
wherein the temporary placement portion is configured from two vertical steps of an upper step support portion and a lower step support portion,
wherein the upper step support portion is the ceiling plate temporary placement portion, and
wherein the lower step support portion is the susceptor temporary placement portion.

5. The vapor phase growth apparatus according to claim 1, wherein the temporary placement apparatus comprises a centering mechanism configured to align a center of the temporarily placed susceptor, susceptor cover, or ceiling plate with a center of the chamber main body.

6. The vapor phase growth apparatus according to claim 5, wherein the centering mechanism comprises a centering piece configured to abut an outer periphery portion of the temporarily placed susceptor, susceptor cover, or ceiling plate at at least three locations, and slightly move the susceptor, susceptor cover, or ceiling plate in a center direction.

7. The vapor phase growth apparatus according to claim 6, wherein the centering piece can be made to protrude based on compressed air.

8. The vapor phase growth apparatus according to claim 1, further comprising:
a transfer arm configured to transfer at least one of the susceptor, the susceptor cover, and the ceiling plate into and out of the chamber;
a nozzle portion configured to ascendably/descendably support the ceiling plate and to supply the raw material gas;
an upthrust ascent/descent mechanism configured to thrust up and ascendably/descendably support from below the susceptor on which placed the susceptor cover is placed or the susceptor cover; and
a control unit configured to control operation of the transfer arm, the nozzle portion, the upthrust ascent/descent mechanism, and the temporary placement apparatus.

9. The vapor phase growth apparatus according to claim 8,
wherein a plurality of through holes are provided on an outer periphery portion of the susceptor, and
wherein the upthrust ascent/descent mechanism comprises:
a plurality of upthrust rods ascendably/descendably erected on an outer periphery portion of the chamber main body;
upthrust ascent/decent means configured to, normally, position an upper end surface of each upthrust rod lower than the susceptor in a state in which the susceptor is provided on the chamber side, and during operation, raise the upper end surface of each upthrust rod above the susceptor cover placed on the susceptor in a state in which the susceptor is provided on the chamber side; and
a function of selecting whether to thrust up the susceptor or to thrust up the susceptor cover by controlling a relative position between a position of each of the through holes and the upper end face of the upthrust rods by rotating the susceptor.

10. The vapor phase growth apparatus according to claim 8,
wherein the control unit comprises a program configured to realize:
a step of transferring with the transfer arm and handing over and holding in the temporary placement apparatus at least one of the susceptor, the susceptor cover, and the ceiling plate;
a step of raising the ceiling plate with the nozzle portion;
a step of raising the susceptor and/or the susceptor cover with the upthrust ascent/descent mechanism;
a step of handing over and transferring a member held by the nozzle portion and/or the upthrust ascent/descent mechanism to the transfer arm;
a step of delivering the ceiling plate to the nozzle portion from the temporary placement apparatus in a state in which the ceiling plate is held; and
a step of delivering the susceptor and/or the susceptor cover to the upthrust ascent/descent mechanism from the temporary placement apparatus in a state in which the susceptor and the susceptor cover are held.

11. The vapor phase growth apparatus according to claim 8,
wherein the transfer arm comprises:
an upper step portion configured to hold the ceiling plate; and
a lower step support portion configured to hold the susceptor and the susceptor cover, or the susceptor cover, and
wherein the transfer arm is capable of holding so that a member held by the upper step support portion and a member held by the lower step support portion do not contact each other.
